(19) United States
(12) Patent Application Publication
(10) Pub. No.: US 2023/0240094 A1
(43) Pub. Date: Jul. 27, 2023

(54) SLURRY FOR POLISHING COPPER, DISPLAY DEVICE MANUFACTURING METHOD USING THE SAME, AND DISPLAY DEVICE

(71) Applicants: Samsung Display Co., LTD., Yongin-si (KR); IUCF-HYU (Industry-University Cooperation Foundation Hanyang University), Seoul (KR)

(72) Inventors: Byoung Kwon CHOO, Hwaseong-si (KR); Jea Gun PARK, Seongnam-si (KR); Seung Bae KANG, Suwon-si (KR); Sungjun KIM, Hwaseong-si (KR); Sung Hoon MOON, Cheonan-si (KR)

(73) Assignees: Samsung Display Co., LTD., Yongin-si (KR); IUCF-HYU (Industry-University Cooperation Foundation Hanyang University), Seoul (KR)

(21) Appl. No.: 18/099,496

(22) Filed: Jan. 20, 2023

(30) Foreign Application Priority Data
Jan. 27, 2022 (KR) 10-2022-0012704

(51) Int. Cl. H10K 59/12; H10K 59/131; H10K 59/124; C09G 1/02

(52) U.S. Cl. CPC H10K 59/1201; H10K 59/131; H10K 59/124; C09G 1/02

(57) ABSTRACT

Embodiments provide a slurry for polishing copper, a manufacturing method of a display device which uses the slurry, and the display device. The slurry for polishing copper includes an abrasive, a catalyst including a single molecule having an iron ion, a polishing suppressant, and an oxidizing agent.

### CROSS-REFERENCE TO RELATED APPLICATION(S)

This application claims priority to and benefits of Korean Patent Application No. 10-2022-0012704 under 35 U.S.C. § 119, filed on Jan. 27, 2022, in the Korean Intellectual Property Office, the entire contents of which are incorporated herein by reference.

### BACKGROUND

### 1. Technical Field

The disclosure relates to a slurry for polishing copper, a manufacturing method of a display device using the same, and a display device.

### 2. Description of the Related Art

A liquid crystal display (LCD), a plasma display panel (PDP), an organic light emitting diode device (OLED device), a field effect display (FED), an electrophoretic display, etc. are known.

Among them, the organic light emitting display has a self-luminance characteristic, and unlike the liquid crystal display, a separate light source may be not required, so thickness and weight may be reduced. The organic light emitting display has high quality characteristics such as low power consumption, high luminance, and fast response speed.

On the other hand, as the display device may be developed with high resolution, the number of wiring layers may be gradually increased, and accordingly, a step reduction and a resistance minimization may be required. In a process in which the metal wirings and the insulating layers may be sequentially stacked, since a surface non-uniformity of each layer may be transferred to the next layer and then be affected, a planarization process that removes the non-uniform curves occurring in each process has been used. For this, several methods may be used, however a chemical mechanical polishing (CMP) method may be used. CMP is a process that polishes the surface to be planarized by providing a slurry including abrasives and various compounds while performing a rotation movement by contacting the surface to be planarized with the polishing pad. It may be required to develop an appropriate polishing slurry that may increase a polishing speed, improve process efficiency, and reduce a thickness when applied to multi-layered wiring depending on the target to which the CMP process may be applied.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments may provide a slurry for polishing copper, a manufacturing method of a display device using the same, and a display device, that may more readily and efficiently perform the process of planarizing the surfaces of the insulating layer and the wiring layer without largely increasing in thickness even if the wiring layers increase when manufacturing the display device, and provide an excellent surface characteristic even for a low-resistance copper wiring layer.

It is apparent that the aspect of the disclosure is not limited to the above-described aspect, but may be variously extended.

A slurry for polishing copper according to an embodiment may include: an abrasive, a catalyst which may include a single molecule which may have an iron ion, a polishing suppressant, and an oxidizing agent.

The catalyst may include at least one selected from iron cyanide, iron nitride, iron citrate, iron chloride, iron sulfate, iron oxalate, iron bromide, and iron phosphate.

The polishing suppressant may be a material that may be combined with a metal ion with one ligand.

The polishing suppressant may be at least one selected from arginine, ethylenediaminetetraacetic acid (EDTA), glycine, citric acid, diethylenetriamine pentamethylene phosphonic acid (DTPMPA), 1-hydroxy ethylidene-1, and 1-diphosphonic acid.

The oxidizing agent may be at least one selected from hydrogen peroxide, ammonium persulfate, benzoyl peroxide, calcium peroxide, barium peroxide, and sodium peroxide.

The abrasive may be at least one selected from silica, zirconia, alumina, ceria, and titania.

The catalyst and the oxidizing agent may react to generate hydroxyl radicals.

The slurry for polishing copper may have a pH in a range of about 8 to about 10.

A content of the catalyst may be in a range of about 0.25 to about 2.0 wt % based on the entire weight of the slurry for polishing copper.

A content of the oxidizing agent may be in a range of about 0.5 to about 2.5 wt % based on the entire weight of the slurry for polishing copper.

A content of the polishing suppressant may be in a range of about 0.25 to about 2.0 wt % based on the entire weight of the slurry for polishing copper.

A display device according to an embodiment may include: a first interlayer insulating layer positioned on a substrate; and at least one first signal line and a first side wall insulating layer positioned on the first interlayer insulating layer, wherein the first side wall insulating layer may be positioned between at least two of the first signal lines, and a height measured from the surface of the substrate to a surface of the at least one first signal line along a first direction perpendicular to the surface of the substrate may be the same as a height measured from the surface of the substrate to a surface of the first side wall insulating layer along the first direction perpendicular to the surface of the substrate.

The at least one first signal line may include copper (Cu).

A surface of at least one first signal line and a surface of the first side wall insulating layer may each be a polished surface.

In at least one first signal line, an angle between the lower surface of the first signal line and the side surface of the first signal line may be 90 degrees or more.

The first interlayer insulating layer may include one or more of a silicon oxide and a silicon nitride.

The display device may further include a second interlayer insulating layer positioned on the at least one first signal line and the first side wall insulating layer, and at least one second signal line and a second side wall insulating layer positioned on the second interlayer insulating layer, and the second side wall insulating layer may be positioned between at least two of the second signal lines, while a height measured from the surface of the substrate to a surface of the at least one second signal line along the first direction perpendicular to the surface of the substrate may be the same as a height measured from the surface of the substrate to a surface of the second side wall insulating layer along the first direction perpendicular to the surface of the substrate.

The at least one second signal line may include copper (Cu).

A surface of the at least one second signal line and the surface of the second side wall insulating layer may each be a polished surface.

In at least one second signal line, the angle between the lower surface of the second signal line and the side surface of the second signal line may be 90 degrees or more.

A manufacturing method of a display device according to an embodiment may include forming a first interlayer insulating layer on a substrate, forming a first side wall insulating layer which may include at least one depression on the first interlayer insulating layer, forming a first conductive layer to cover at least one depression on the first interlayer insulating layer and the first side wall insulating layer, and forming at least one first signal line by polishing the first conductive layer and the first side wall insulating layer, wherein a height measured from a surface of the substrate to a surface of the at least one first signal line along a first direction perpendicular to the surface of the substrate may be the same as a height from the surface of the substrate to a surface of the first side wall insulating layer along the first direction perpendicular to the surface of the substrate.

The at least one first signal line may include copper (Cu), and the polishing of the upper part of the first conductive layer may be performed by using a slurry for polishing copper which may include an abrasive, a catalyst including a single molecule with an iron ion, a polishing suppressant, and an oxidizing agent.

The manufacturing method may further include planarizing the surface of the first interlayer insulating layer, and the planarization of the surface of the first interlayer insulating layer may not use the slurry for polishing copper.

A surface of the at least one signal line and a surface of the first side wall insulating layer may each be polished by the polishing of the upper part of the first conductive layer.

The manufacturing method may further include forming a second interlayer insulating layer on at the least one first signal line and the first side wall insulating layer, and the forming of the second interlayer insulating layer may not include an additional planarization process.

The manufacturing method of the display device may further include forming a second side wall insulating layer which may include at least one depression on the second interlayer insulating layer, and forming a second conductive layer to cover at least one depression on the second interlayer insulating layer and the second side wall insulating layer, wherein an upper part of the second conductive layer may be polished to form at least one second signal line, and a height measured from the surface of the substrate to a surface of the at least one second signal line along the first direction perpendicular to the surface of the substrate may be the same as a height measured from the surface of the substrate to a surface of the second side wall insulating layer along the first direction perpendicular to the surface of the substrate.

The at least one second signal line may include copper (Cu), and the polishing of the upper part of the second conductive layer may be performed by using a slurry for polishing copper which may include an abrasive, a catalyst which may include a single molecule with an iron ion, a polishing suppressant, and an oxidizing agent.

A surface of the at least one signal line and a surface of the second side wall insulating layer may each be polished by the polishing of the upper part of the second conductive layer.

According to embodiments, by simultaneously planarizing the insulating layer and the metal film when manufacturing the display device, even if the wiring layer thickness increases, the thickness increase may not be large, and the process of the planarization of the surface of the insulating layer and the wiring layer may be performed more readily and efficiently, and an excellent surface characteristic may be imparted to a low-resistance copper wiring layer, thereby realizing a high-step stacked structure of high resolution.

It is to be understood that the embodiments above are described in a generic and explanatory sense only and not for the purpose of limitation, and the disclosure is not limited to the embodiments described above.

### BRIEF DESCRIPTION OF THE DRAWINGS

The above and other aspects, and features, of the disclosure will be more apparent by describing in detail embodiments thereof with reference to the accompanying drawings, in which:

FIG. 1 is a schematic cross-sectional view of an operation of a slurry for polishing copper according to an embodiment;

FIG. 2 is a schematic diagram of an equivalent circuit of a pixel of a display device according to an embodiment;

FIG. 3 is a schematic cross-sectional view showing a part of one equivalent circuit of a pixel of a display device according to an embodiment;

FIG. 4A to FIG. 4J are schematic cross-sectional views showing a manufacturing method of a display device according to an embodiment;

FIG. 5 is a schematic diagram of an equivalent circuit of a pixel of a display device according to another embodiment;

FIG. 6 is a schematic layout view of an equivalent circuit of one pixel of a display device according to another embodiment;

FIG. 7 is a schematic cross-sectional view taken along a line VII-VII of FIG. 6 according to an embodiment; and

FIG. 8A to FIG. 8M are schematic cross-sectional views showing a manufacturing method of a display device according to another embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

It will be understood that the terms “connected to” or “coupled to” may include a physical or electrical connection or coupling.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

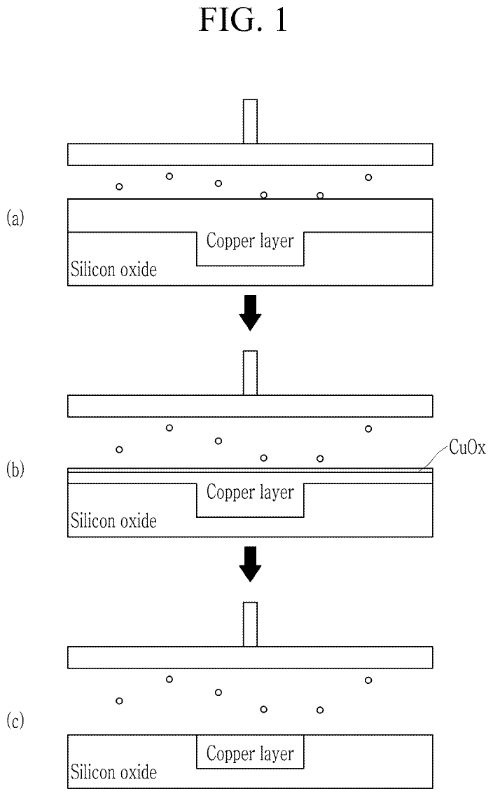

First, a slurry for polishing copper according to an embodiment may be described with reference to FIG. 1. FIG. 1 is a schematic view of an operation of a slurry for polishing copper according to an embodiment.

A slurry for polishing copper according to one embodiment may include an abrasive, a catalyst including a single molecule having iron ions, a polishing suppressant, and an oxidizing agent.

The abrasive may be a particle-phase material that advances polishing by applying a physical force to the surface of the polishing target, and may include a metal oxide, inorganic particles of a surface-modified metal oxide, and a metal oxide in a colloidal state. For example, it may be at least one selected from silica, zirconia, alumina, ceria, and titania. Such abrasive may exist in a particle state and may be included in a content in a range of about 0.5 wt % to about 5.0 wt % with respect to the entire weight of the slurry. A content of less than 0.5 wt % may lead to the polishing speed being reduced, and at a content of more than 5.0 wt %, defects may occur due to the abrasive.

The catalyst including the single molecule including the iron ions may be a material that activates a radical generation by causing a Fenton reaction with the oxidizing agent. For example, the single molecule having the iron ions may react with the oxidizing agent to generate a hydroxyl radical, and this reaction may be called a Fenton reaction. Since the hydroxyl radical generated in this way has high oxidizing power, it may be possible to rapidly oxidize a metal film serving as a polishing target, and more specifically, a copper film, thereby it may be easier to perform mechanical polishing by the abrasive. The catalyst including the single molecule having such an iron ion may include at least one selected from iron cyanide, iron nitride, iron citrate, iron chloride, iron sulfate, iron oxalate, iron bromide, and iron phosphate. These catalysts may be included in a content in a range of about 0.25 wt % to about 2.0 wt % based on the entire weight of the slurry. If it is less than 0.25 wt %, the oxidation of the copper film may not be sufficiently performed, and if it exceeds 2.0 wt %, dispersion stability may deteriorate.

The oxidizing agent may be a material that reacts with the catalyst including the single molecule including the iron ions to react with hydroxyl radicals and may be a material that may generate dissolved oxygen in the slurry. Examples of such oxidizing agents include at least one selected from hydrogen peroxide, ammonium persulfate, benzoyl peroxide, calcium peroxide, barium peroxide, and sodium peroxide. The oxidizing agent may be included in a content in a range of about 0.5 wt % to about 2.5 wt % based on the entire weight of the slurry.

The polishing suppressant may be a material capable of binding to a metal ion with a single ligand. By using the polishing suppressant, it may be possible to control the selectivity between the copper film and the insulating layer during the polishing. For example, by combining with the copper ions or the iron ions to form a reversible complex, it may be possible to control the reaction speed. The polishing suppressant may be at least one selected from arginine, ethylenediaminetetraacetic acid (EDTA), glycine, citric acid, diethylenetriamine pentamethylene phosphonic acid (DTPMPA), 1-hydroxy ethylidene-1, and 1-diphosphonic acid. The polishing suppressant may be included in a content in a range of about 0.25 to about 2.0 wt % based on the entire amount of the slurry. If it is less than 0.25 wt %, a polishing rate may decrease, and the polishing target film stop function may deteriorate, while if it exceeds 2.0 wt %, it may adsorb polishing particles and cause defects or scratches.

The slurry for polishing copper according to one embodiment may further include a pH adjusting agent. By including the pH adjusting agent, the stability of the slurry may be secured, and it may be possible to provide a favorable environment for the reaction of the catalyst and the oxidizing agent included in the slurry. In the slurry for polishing copper according to one embodiment, the pH may be in a range of about 8 to about 10, that is, a basic environment.

The slurry for polishing copper according to one embodiment may further include a corrosion inhibitor, a dispersant, and other additives with these components.

The single molecule having iron ions and the oxidizing agent included in the slurry for polishing copper according to one embodiment may cause a Fenton reaction that may generate a hydroxyl radical by the reaction. Since the generated hydroxyl radical has a high oxidizing power, it may quickly oxidize the metal film, thereby accelerating the mechanical polishing by the abrasive. Therefore, when using the slurry for polishing copper according to one embodiment, in the case of polishing the cooper layer formed on the insulating layer such as silicon oxide, the copper layer and the silicon oxide layer having excellent surface quality may be obtained only by one-step polishing without two-step polishing.

For example, as shown in FIG. 1, by polishing (a Cu CMP) the copper layer after forming the copper layer on the insulating layer (a silicon oxide layer) in which a groove may be formed, it may be possible to form the wiring made of copper at the desired position, that is, the portion where the groove may be formed. In general, the polishing can be accomplished by relatively moving the polishing target layer and the polishing pad in the contact with each other while supplying the slurry including the abrasive between the polishing pad and the polishing target layer. FIG. 1 shows that only copper may be filled in the groove of the insulating layer, but embodiments are not limited thereto, and a barrier layer may be further formed on the insulating layer and the copper interface. As the barrier layer, unlike copper, a material having a low polishing rate may be used for the slurry for polishing copper according to one embodiment, and for example, a thin film including at least one selected from titanium (Ti), tantalum (Ta), ruthenium (Ru), molybdenum (Mo), cobalt (Co), gold (Au) and the like may be used.

In the polishing of the copper layer under these conditions, conventionally, the copper part may be polished using a slurry with a high polishing amount for copper, and when the silicon oxide layer may be exposed, secondary polishing may be performed with the same speed for the copper layer and the silicon oxide layer. Such secondary polishing may be essential to make the surfaces of copper and silicon oxide layers having different polishing characteristics uniform and to prevent surface defects such as dishing and erosion. However, there may be a problem that the dishing may not be sufficiently removed even in the secondary polishing, and the cost may be high and process efficiency deteriorates by performing two polishing steps.

On the other hand, when the slurry for polishing copper according to one embodiment may be applied as the polishing slurry, the copper on the surface may be oxidized by the action of hydroxyl radicals generated by the reaction of the catalyst including the single molecule with iron ions and the oxidizing agent and copper oxide (CuOₓ) may be formed (referring to FIG. 1(b)). In such a copper oxide layer, the polishing by the abrasive may proceed faster than with copper, so it may be possible to improve the polishing speed of the copper layer, thus preventing the dishing, etc. from occurring on the surface of the polishing target film and improving the uniformity of the polishing target film. When applying the slurry for polishing copper according to one embodiment as the polishing slurry, copper may not be oxidized by simply using the oxidizing agent, but copper may be oxidized by hydroxyl radicals generated through the Fenton reaction, and accordingly, since the reaction speed may be further improved, the copper layer may be polished to have the uniform surface without the dishing even if without the additional polishing in two steps.

Therefore, this slurry for polishing copper may be efficiently applied when manufacturing a display device, when forming the copper wiring, which may be low-resistance wiring. As a result, even in the process of forming the multi-layered wiring, since the number of polishing processes may be reduced, the process efficiency may be improved, and the performance of the entire device may also be improved because the wiring surface characteristic may be excellent.

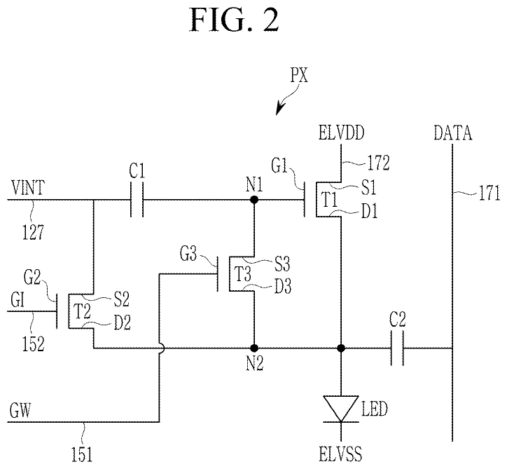

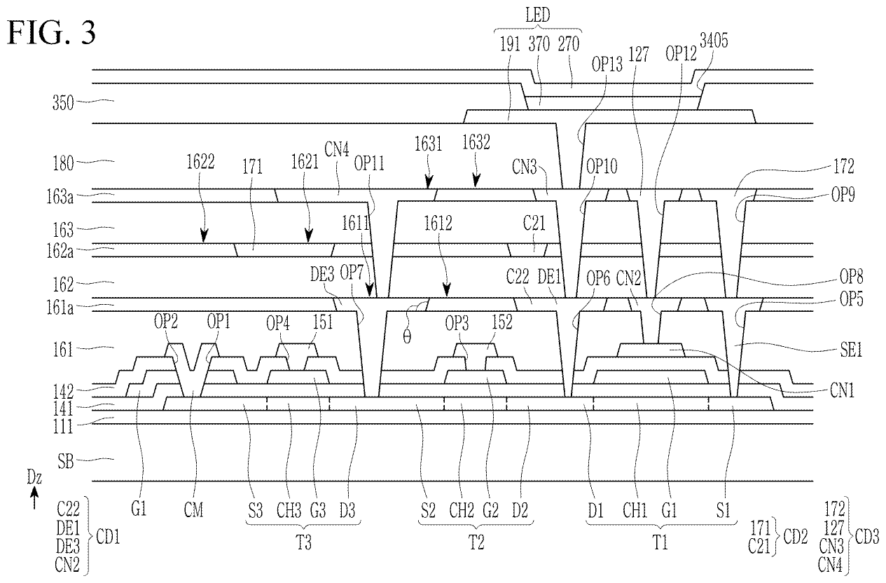

Accordingly, a display device according to an embodiment will be described, with reference to FIG. 2 and FIG. 3. The display device according to an embodiment includes an example structure that may be manufactured by applying the slurry for polishing the copper described above. FIG. 2 is a schematic diagram of an equivalent circuit of a pixel of a display device according to an embodiment, and FIG. 3 is a schematic cross-sectional view showing a part of an equivalent circuit of one pixel of a display device according to an embodiment.

Referring to FIG. 2, the pixel PX may include three transistors T1, T2, and T3, two capacitors C1 and C2, and a light emitting diode (LED), which may be connected directly or indirectly to signal lines 151, 152, 171, 172, and 127.

The signal lines 151, 152, 171, 172, and 127 may include a first scan line 151 transmitting a gate signal GW, a second scan line 152 transmitting a scan signal GI, a data line 171 transmitting a data voltage DATA, a driving voltage line 172 transmitting a driving voltage ELVDD, and an initialization voltage layer 127 transmitting an initialization voltage VINT.

The transistors T1, T2, and T3 may include a first transistor T1, a second transistor T2, and a third transistor T3. The transistors T1, T2, and T3 may be N-type transistors. However, in another embodiment, the transistors T1, T2, and T3 may be P-type transistors, and may include an N-type transistor and a P-type transistor.

The first transistor T1 may include a first gate electrode G1 (also called a control electrode) connected to a first node N1, a first source electrode S1 (also called a first electrode or an input electrode) connected to the driving voltage line 172, and a first drain electrode D1 (also called a second electrode or an output electrode) connected to a second node N2. The first transistor T1 may be a transistor that outputs a driving current to the light emitting diode LED, and may be referred to as a driving transistor.

The driving voltage ELVDD applied to the first source electrode S1 through the driving voltage line 172 may have a high voltage of a high level and a low voltage of a low level.

The second transistor T2 includes a second gate electrode G2 connected to the second scan line 152, a second source electrode S2 connected to the initialization voltage layer 127, and a second drain electrode D2 connected to the second node N2. The scan signal GI applied to the second gate electrode G2 through the second scan line 152 may have a high voltage and a low voltage for turning the second transistor T2 on and off.

The initialization voltage VINT applied through the initialization voltage layer 127 may have a high voltage to turn on the first transistor T1, a low voltage to initialize the anode of the light emitting diode LED, and a reset voltage to reset the anode. The reset voltage may be lower or higher than the low voltage of the initialization voltage VINT.

The third transistor T3 includes a third gate electrode G3 connected to the first scan line 151, a third source electrode S3 connected to the first node N1, and a third drain electrode D3 connected to the second node N2.

The gate signal GW applied to the gate electrode G3 through the first scan line 151 may have a high voltage and a low voltage for turning the third transistor T3 on and off.

The first capacitor C1 may be connected between the initialization voltage layer 127 and the first node N1. The first capacitor C1 may store the voltage of the first node N1. The first capacitor C1 may be referred to as a storage capacitor.

The second capacitor C2 may be connected between the second node N2 and the data line 171. The second capacitor C2 may write the data voltage DATA transmitted through the data line 171. The second capacitor C2 may be referred to as a programming capacitor.

The first and second capacitors C1 and C2 may be electrically connected in series by the third transistor T3, and the data voltage DATA may be distributed by the first and second capacitors C1 and C2 and applied to the first node N1.

The light emitting diode LED may include an anode connected to the second node N2 and a cathode to which a common voltage ELVSS may be applied. When the first transistor T1 is turned on, the driving current corresponding to the data voltage DATA applied to the first node N1 flows through the light emitting diode LED, and the light emitting diode LED may emit light with a luminance.

In the above, it has been described that one pixel PX includes three transistors T1 to T3 and two capacitors C1 and C2, but is not limited thereto, and the number of transistors and capacitors and their connection relationships may be variously changed.

According to the embodiment shown in FIG. 3, for better comprehension and ease of description, the first transistor T1 to the third transistor T3 and the light emitting diode LED connected to the first transistor T1 are shown, however it is not limited thereto, and as previously described with reference to FIG. 2, other transistors and capacitors may be included.

The substrate SB may include an insulating material such as a polymer such as a polyimide and a polyamide, or glass, and may be optically transparent.

The substrate SB may include a first transparent layer (not shown) and a second transparent layer (not shown) overlapping each other, and a first barrier layer (not shown) positioned between the first transparent layer and the second transparent layer.

The first transparent layer and the second transparent layer may include polymers such as a polyimide and a polyamide. The first transparent layer and the second transparent layer may include at least one among polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

The barrier layer may prevent penetration of moisture, etc., and may include inorganic insulating materials such as a silicon oxide (SiOₓ), a silicon nitride (SiNₓ), and a silicon oxynitride (SiOₓN_{y}). The barrier layer may include amorphous silicon (a-Si).

A buffer layer 111 may be positioned between the substrate SB and the semiconductor layer 130 to block impurities from the substrate SB during the crystallization process to form a polysilicon, thereby improving the polysilicon characteristics.

The buffer layer 111 may include an inorganic insulating material such as a silicon oxide (SiOₓ), a silicon nitride (SiNₓ), and a silicon oxynitride (SiOₓN_{y}). The buffer layer 111 may include amorphous silicon (Si).

The semiconductor layers CH1, CH2, CH3, S1, S2, S3, D1, D2, and D3 may include a first channel region CH1, a first source region S1, and a first drain region D1 of the first transistor T1, a second channel region CH2, a second source region S2, and a second drain region D2 of the second transistor T2, and a third channel region CH3, a third source region S3, and a third drain region D3 of the third transistor T3.

The semiconductor layers CH1, CH2, CH3, S1, S2, S3, D1, D2, and D3 may include a semiconductor material such as a polysilicon, an amorphous silicon, and an oxide semiconductor.

A gate insulating layer 141 may be positioned on the semiconductor layers CH1, CH2, CH3, S1, S2, S3, D1, D2, and D3, and the gate insulating layer 141 may be a single layer or a multi-layered structure including a silicon nitride, a silicon oxide, a silicon oxynitride, etc.

A first gate conductor including a first gate electrode G1, a second gate electrode G2, and a third gate electrode G3 may be positioned on the gate insulating layer 141.

The first gate electrode G1, the second gate electrode G2, and the third gate electrode G3 may have an approximately rectangular shape or an island shape. The first gate conductor may include molybdenum (Mo), aluminum (Al), copper (Cu), and/or titanium (Ti), and may have a single-layered or multi-layered structure including these.

A second gate insulating layer 142 may be positioned on the first gate conductor. A silicon nitride, a silicon oxide, a silicon oxynitride, etc. may be included. The second gate insulating layer 142 may have a single-layered or multi-layered structure including a silicon nitride, a silicon oxide, and a silicon oxynitride.

A second gate conductor including a first scan line 151, a second scan line 152, a first connection electrode CN1, and a connecting member CM may be positioned on the second gate insulating layer 142. The second gate conductor may include molybdenum (Mo), aluminum (Al), copper (Cu), silver (Ag), chromium (Cr), tantalum (Ta), titanium (Ti), etc., and may be a single-layered or multi-layered structure including the same.

The first connection electrode CN1 may be connected to the initialization voltage layer 127 and overlap the first gate electrode G1. A portion where the first connection electrode CN1 and the first gate electrode G1 overlap each other may form a first capacitor C1 together with the second gate insulating layer 142.

The first gate insulating layer 141 and the second gate insulating layer 142 may have a first contact hole OP1 exposing the third source electrode S3, the second gate insulating layer 142 may include a second contact hole OP2 exposing the first gate electrode G1, and the connecting member CM may connect the first gate electrode G1 to the third source electrode S3 by a side contact method. In the illustrated embodiment, it may be described that the first gate electrode G1 may be separated from both sides, but this may be for convenience of description, and the first gate electrodes G1 may be connected to each other.

The second gate insulating layer 142 may have a third contact hole OP3 exposing the second gate electrode G2 and a fourth contact hole OP4 exposing the third gate electrode G3, the first scan line 151 may be connected to the third gate electrode G3 through the fourth contact hole OP4 to transmit the gate signal GW, and the second scan line 152 may be connected to the second gate electrode G2 through the third contact hole OP3 to transmit the scan signal GI.

A first interlayer insulating layer 161 and a first side wall insulating layer 161a may be positioned on the second gate conductor. The first interlayer insulating layer 161 may have a constant height measured from the substrate surface along the first direction Dz. For example, the surface of the first interlayer insulating layer 161 may be planarized. The first interlayer insulating layer 161 may include a silicon nitride, a silicon oxide, a silicon oxynitride, or the like. The first interlayer insulating layer 161 may be formed of a multi-layer in which a layer including a silicon nitride and a layer including a silicon oxide may be stacked. For example, in the illustrated embodiment, the first interlayer insulating layer 161 is illustrated as being composed of one layer, but embodiments are not limited thereto, and the first interlayer insulating layer 161 may be formed of a first layer containing a silicon nitride and a second layer containing a silicon oxide, and the first layer including a silicon nitride may serve as a stopper in the planarization process of the second layer including a silicon oxide. Accordingly, a portion of the first interlayer insulating layer 161 may have the same height as the surface of the first layer.

A first side wall insulating layer 161a may be positioned on the first interlayer insulating layer 161. The first side wall insulating layer 161a may be made of a silicon oxide or a silicon nitride. In the polishing process after a formation of a metal wiring to be described later, it may be polished in the same process as the metal wiring (a conductor).

The first interlayer insulating layer 161 and the first side wall insulating layer 161a, the second gate insulating layer 142, the first gate insulating layer 141 may have a fifth contact hole OP5 and a sixth contact hole OP6 exposing the first source region S1 and the first drain region D1 of the first transistor T1, and a seventh contact hole OP7 exposing the third drain region D3 of the third transistor T3. Although not shown, other contact holes may be further formed in the first interlayer insulating layer 161 and the first side wall insulating layer 161a, the second gate insulating layer 142, and the first gate insulating layer 141. The size of each contact hole may be formed to be larger in a portion corresponding to the first side wall insulating layer 161a.

An eighth contact hole OP8 exposing the first connection electrode CN1 may be formed in the first interlayer insulating layer 161 and the first side wall insulating layer 161a. The size of the eighth contact hole OP8 may be larger in the portion corresponding to the first side wall insulating layer 161a.

A first data conductor CD1 including a first source electrode SE1, a first drain electrode DE1, a third drain electrode DE3, and a second connection electrode CN2 may be positioned on the first interlayer insulating layer 161. The first data conductor CD1 may include aluminum (Al), molybdenum (Mo), titanium (Ti), tungsten (W), and/or copper (Cu), and a single layered or multi-layered structure including the same. For example, in the first data conductor, the first source electrode SE1, the first drain electrode DE1, the second source electrode SE2, and the second drain electrode DE2 may be a triple-layered structure including a lower layer formed of a refractory metal such as titanium, molybdenum, chromium, and tantalum, etc. or alloys thereof, a middle layer having lower resistivity such as an aluminum-based metal, a silver-based metal, and a copper-based metal, and an upper layer formed of a refractory metal such as titanium, molybdenum, chromium, and tantalum, etc. When implementing the low-resistance wiring and applying the slurry for polishing copper described above, copper may be included.

The first source electrode SE and the first drain electrode DE1 may be connected to the first source region S1 and the first drain region D1 of the first transistor T1 through the fifth contact hole OP5 and the sixth contact hole OP6, respectively. The third drain electrode DE3 may be connected to the third drain region D3 of the third transistor T3 through the seventh contact hole OP7. The second connection electrode CN2 may be connected to the first connection electrode CN1 through the eighth contact hole OP8.

As above-described, according to the display device according to the embodiment, the first side wall insulating layer 161a may be polished together with the metal wiring (the conductor) in the polishing process after the formation of the metal wiring. For example, when the first data conductor CD1 including the first source electrode SE1, the first drain electrode DE1, the third drain electrode DE3, and the second connection electrode CN2 are formed and the polishing process is performed thereon, by using the polishing slurry described above, the first data conductor CD1 made of the metal (for example, copper) and the first side wall insulating layer 161a may be polished together in one process. Accordingly, the first metal surface 1611 of the wirings (i.e., the first source electrode SE1, the first drain electrode DE1, the third drain electrode DE3, and the second connection electrode CN2, etc.) included in the first data conductor CD1 and the first insulating surface 1612 of the first side wall insulating layer 161a have the same height, and they all have a polished surface. Here, the surface height of each layer may be the height measured from the substrate surface along the first direction Dz. As described above, since the surface height of the first data conductor CD1 and the first side wall insulating layer 161a may be the same, a subsequent process may be performed without an additional planarization process.

The angle θ formed between the lower surface of the first data conductor CD1 and the side surface of the first data conductor CD1 may be 90 degrees or more. For example, the lower surface of the first data conductor CD1 and the side surface of the first data conductor CD1 meet while forming an obtuse angle. This, like the later-described manufacturing method, may be the shape that appears because the first side wall insulating layer 161a may be first formed and etched to prepare the portion where the first data conductor CD1 may be formed, and the excess metal and the first side wall insulating layer 161a may be polished together. On the other hand, in the process of forming the wiring using the conductor first, forming an insulating layer to cover it, and etching the insulating layer to expose the wiring may be performed, and since the wiring may be patterned first, the side surface and the lower surface of the wiring form an acute angle. As described above, in the configuration according to the embodiment in which the lower surface of the first data conductor CD1 and the side surface of the first data conductor CD1 form the obtuse angle with respect to each other, the area of the upper surface exposed upward may be formed to be wider, so that a degree of freedom may be further increased in the connection with the upper conductors in a subsequent process.

A second interlayer insulating layer 162 may be positioned on the first data conductor CD1. The height of the second interlayer insulating layer 162 measured from the substrate surface along the first direction Dz may be constant. For example, the surface of the second interlayer insulating layer 162 may be planarized. As described above, since the surface heights of the first data conductor CD1 disposed under the second interlayer insulating layer 162 and the first side wall insulating layer 161a may be the same, the second interlayer insulating layer 162 of which the surface height may be constant even without an additional planarization process for the second interlayer insulating layer 162 may be obtained. The second interlayer insulating layer 162 may include an insulating material, and for example, the second interlayer insulating layer 162 may include a silicon oxide.

On the second interlayer insulating layer 162, a second side wall insulating layer 162a may be positioned. The second side wall insulating layer 162a may be made of a silicon oxide or a silicon nitride. In the polishing process after the formation of the metal wiring to be described later, the second side wall insulating layer 162a may be polished in the same process as the metal wiring (the conductor).

A second data conductor CD2 including the data line 171 may be positioned on the second interlayer insulating layer 162. The second data conductor CD2 may include aluminum (Al), silver (Ag), magnesium (Mg), gold (Au), nickel (Ni), chromium (Cr), calcium (Ca), molybdenum (Mo), titanium (Ti), tungsten (W), and/or copper (Cu), and the like, and may have a single-layered or multi-layered structure including the same. When implementing the low-resistance wiring and applying the slurry for polishing copper described above, copper may be included. The data line 171 may include the first electrode C21 of the extended second capacitor C2. The extended portion of the first drain electrode DE1 may form the second electrode C22 of the second capacitor C2, and the first electrode C21 and the second electrode C22 may overlap via the second interlayer insulating layer 162 therebetween to form a part of the second capacitor C2.

The data line 171 and the first electrode C21 of the second capacitor C1 may be polished and formed together in one process with the second side wall insulating layer 162a. Therefore, the second metal surface 1621 of the wirings (i.e., the data line 171 and the second capacitor C1, etc.) included in the second data conductor CD2 and the second insulating surface 1622 of the second side wall insulating layer 162a have the same height, and they all have the surface that has been polished. As described above, since the surface heights of the second data conductor CD2 and the second side wall insulating layer 162a may be the same, a subsequent process may be performed without an additional planarization process.

In addition, the angle θ between the lower surface of the second data conductor CD2 and the side surface of the second data conductor CD2 may be 90 degrees or more. For example, the lower surface of the second data conductor CD2 and the side surface of the second data conductor CD2 meet while forming the obtuse angle. This, like the later-described manufacturing method, may be the shape that appears because the second side wall insulating layer 162a may be first formed and etched to prepare the portion where the second data conductor CD2 may be formed, and the excess metal and the second side wall insulating layer 162a may be polished together. On the other hand, in the process of forming the wiring using the conductor first, forming an insulating layer to cover it, and etching the insulating layer to expose the wiring, since the wiring may be patterned first, the side surface and the lower surface of the wiring form an acute angle. As described above, in the configuration according to the embodiment in which the lower surface of the second data conductor CD2 and the side surface of the second data conductor CD2 form the obtuse angle with respect to each other, the area of the upper surface exposed upward may be formed to be wider, so that a degree of freedom may be further increased in the connection with the upper conductors in a subsequent process.

A third interlayer insulating layer 163 and a third side wall insulating layer 163a may be positioned on the second data conductor CD2. The third interlayer insulating layer 163 may have a constant height measured from the substrate surface along the first direction Dz. For example, the surface of the third interlayer insulating layer 163 may be planarized. As described above, since the surface heights of the second data conductor CD2 disposed under the third interlayer insulating layer 163 and the second side wall insulating layer 162a may be the same, the third interlayer insulating layer 163 of which the surface height may be constant even without an additional planarization process for the third interlayer insulating layer 163 may be obtained. The second interlayer insulating layer 163 may include an insulating material, and for example, the third interlayer insulating layer 163 may include a silicon oxide.

A third side wall insulating layer 163a may be positioned on the third interlayer insulating layer 163. The third side wall insulating layer 163a may be formed of a silicon oxide or a silicon nitride. In the polishing process after the formation of the metal wiring to be described later, the third side wall insulating layer 163a may be polished in the same process as the metal wiring (the conductor).

The second interlayer insulating layer 162, the second side wall insulating layer 162a, the third interlayer insulating layer 163, and the third side wall insulating layer 163a may have a ninth contact hole OP9 and a tenth contact hole OP10 exposing the first source electrode SE1 and the first drain electrode DE1 of the first transistor T1, and an eleventh contact hole OP11 exposing the third drain electrode DE3 of the third transistor T3. Also, the second interlayer insulating layer 162, the second side wall insulating layer 162a, the third interlayer insulating layer 163, and the third side wall insulating layer 163a may have a twelfth contact hole OP12 exposing the second connection electrode CN2. The size of each contact hole may be formed larger in a portion corresponding to the third side wall insulating layer 163a.

On the third interlayer insulating layer 163, a third data conductor CD3 including the initialization voltage layer 127, the driving voltage line 172, the third connection electrode CN3, and the fourth connection electrode CN4 may be positioned. When implementing the low-resistance wiring and applying the slurry for polishing copper described above, the third data conductor CD3 may include copper. The driving voltage line 172 may be connected to the first source electrode SE1 of the first transistor T1 through the ninth contact hole OP9, the third connection electrode CN3 may be connected to the first drain electrode DE1 of the first transistor T1 through the tenth contact hole OP10, and the fourth connection electrode CN4 may be connected to the third drain electrode DE3 of the third transistor T3 through the eleventh contact hole OP11. The initialization voltage layer 127 may be connected to the second connection electrode CN2 through the twelfth contact hole OP12, thereby transmitting the initialization voltage VINT to the first gate electrode G1 of the first transistor T1.

The fourth connection electrode CN4 connected to the third drain electrode DE3 of the third transistor T3 overlaps the data line 171 via the third interlayer insulating layer 163 interposed therebetween, thereby forming a portion of the second capacitor C2.

The initialization voltage layer 127, the driving voltage line 172, the third connection electrode CN3, and the fourth connection electrode CN4 may be polished and formed together with the third side wall insulating layer 163a in one process. Accordingly, the third metal surface 1631 of the wirings (i.e., the initialization voltage layer 127, the driving voltage line 172, the third connection electrode CN3, the fourth connection electrode CN4, etc.) included in the third data conductor CD3 and the third insulating surface 1632 of the third side wall insulating layer 163a may have the same height. As described above, since the surface heights of the third data conductor CD3 and the third side wall insulating layer 163a may be the same, a subsequent process may be performed without an additional planarization process.

An insulating layer 180 may be positioned on the third data conductor CD3, and the insulating layer 180 may have a thirteenth contact hole OP13 exposing the third connection electrode CN3 connected to the first drain electrode DE1 of the first transistor T1.

A pixel electrode 191 connected to the third connection electrode CN3 through the thirteenth contact hole OP13 may be positioned on the insulating layer 180. The pixel electrode 191 may be connected to the first drain electrode DE1 of the first transistor T1 through the third connection electrode CN3. The pixel electrode 191 may be individually positioned for each pixel PX. The pixel electrode 191 may include a metal such as silver (Ag), lithium (Li), calcium (Ca), aluminum (Al), magnesium (Mg), or gold (Au), and may include a transparent conductive oxide (TCO) such as an indium tin oxide (ITO) and an indium zinc oxide (IZO). The pixel electrode 191 may be formed of a single layer including a metal material or a transparent conductive oxide, or a multilayer including these. For example, the pixel electrode 191 may have a triple layer structure of indium tin oxide (ITO)/silver (Ag)/indium tin oxide (ITO).

A pixel definition layer 350 may be positioned on the pixel electrode 191. The pixel definition layer 350 may include an organic insulating material such as a generally-used polymer such as poly(methyl methacrylate) (PMMA) or polystyrene (PS), a polymer derivative having a phenol-based group, an acryl-based polymer, an imide-based polymer, a polyimide, an acryl-based polymer, and a siloxane-based polymer. The pixel definition layer 350 may not transmit light by including a black dye.

A pixel opening 3405 of the pixel definition layer 350 may be formed, and the pixel opening 3405 of the pixel definition layer 350 may overlap the pixel electrode 191. An emission layer 370 may be positioned within the pixel opening 3405 of the pixel definition layer 350.

The emission layer 370 may include a material layer that uniquely emits light of primary colors such as red, green, and blue. The emission layer 370 may have a structure in which material layers emitting light of different colors may be stacked.

For example, the emission layer 370 may be an organic emission layer, and the organic emission layer may include an emission layer and one or more of a hole-injection layer (HIL), a hole-transporting layer (HTL), an electron-transporting layer (ETL), and an electron-injection layer (EIL).

A common electrode 270 may be positioned on the emission layer 370 and the pixel definition layer 350. The common electrode 270 may be provided in common to all pixels PX, and may receive a common voltage ELVSS through a common voltage transmitting part (not shown) of a non-display area PA.

The common electrode 270 may include a reflective metal including calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), lithium (Li), calcium (Ca), etc., or a transparent conductive oxide (TCO) such as an indium tin oxide (ITO) and an indium zinc oxide (IZO).

The pixel electrode 191, the emission layer 370, and the common electrode 270 may form the light emitting diode LED. Here, the pixel electrode 191 may be an anode that may be a hole injection electrode, and the common electrode 270 may be a cathode that may be an electron injection electrode. However, embodiments are not limited thereto, and depending on the driving method of the organic light emitting device, the pixel electrode 191 may be a cathode and the common electrode 270 may be an anode.

Holes and electrons from each of the pixel electrode 191 and the common electrode 270 may be injected into the emission layer 370, and an exciton that may be formed by the combination of the injected hole and the electron falls from an excited state to a ground state, thereby emitting light.

Although not shown, an encapsulation layer (not shown) may be positioned on the common electrode 270, and the encapsulation layer may cover the side surface as well as the upper surface of the pixel to seal the pixel part. The encapsulation layer may include multiple layers, and among them, may be formed as a composite film including both an inorganic film and an organic film.

As such, according to the display device according to one embodiment,

The first data conductor CD1, the second data conductor CD2, and the third data conductor CD3 constituting the metal wiring have the same height as the surface of the first side wall insulating layer 161a, the second side wall insulating layer 162a, and the third side wall insulating layer 163a, respectively, so that the conductor and the insulating layer may be formed to have the planarized surface. Accordingly, the surface of the subsequently formed layer may be formed flat without additional processing, and even if multiple wirings may be stacked, it may be possible to be formed without increasing the thickness of the entire device, thereby high-resolution may be formed and a high-step stacked structure may be enabled. In the embodiment, it has been described that the first data conductor CD1, the second data conductor CD2, and the third data conductor CD3 may be all made of the copper wiring so that the slurry for polishing copper may be applied, but the disclosure is not limited thereto, and it may also be possible to be applied to one or more of these and is not limited to the configuration described in the embodiments.

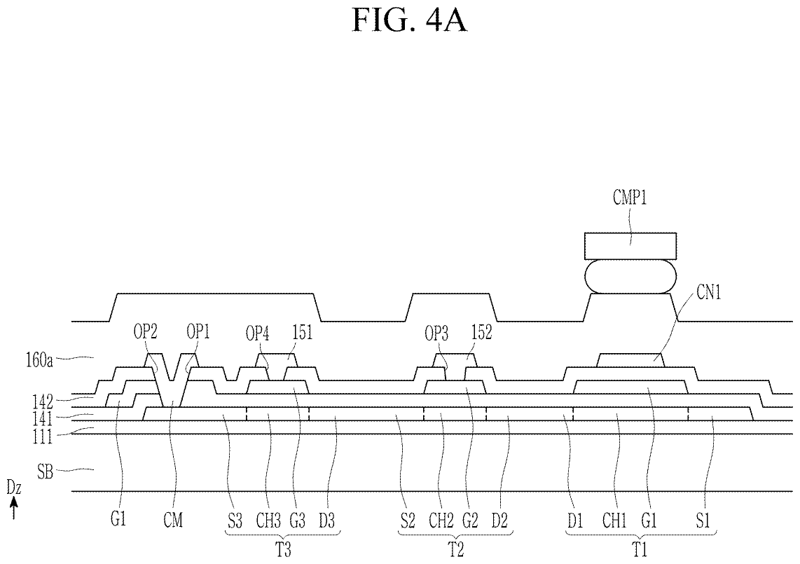

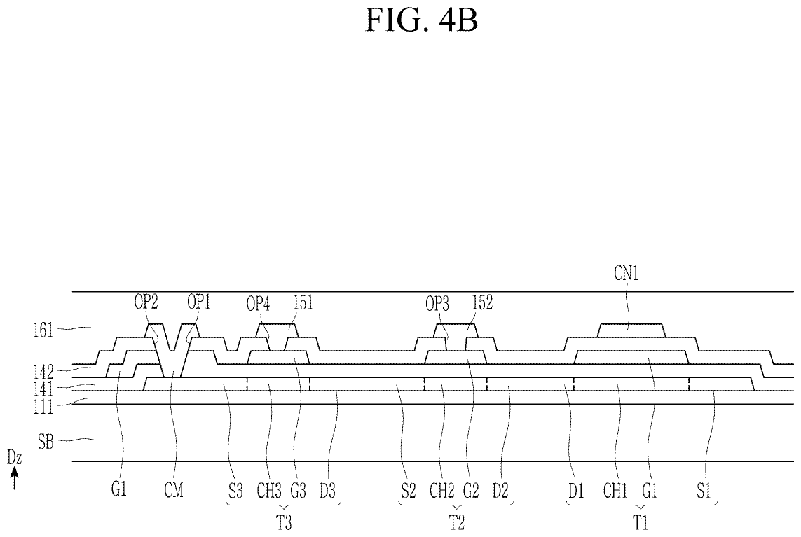

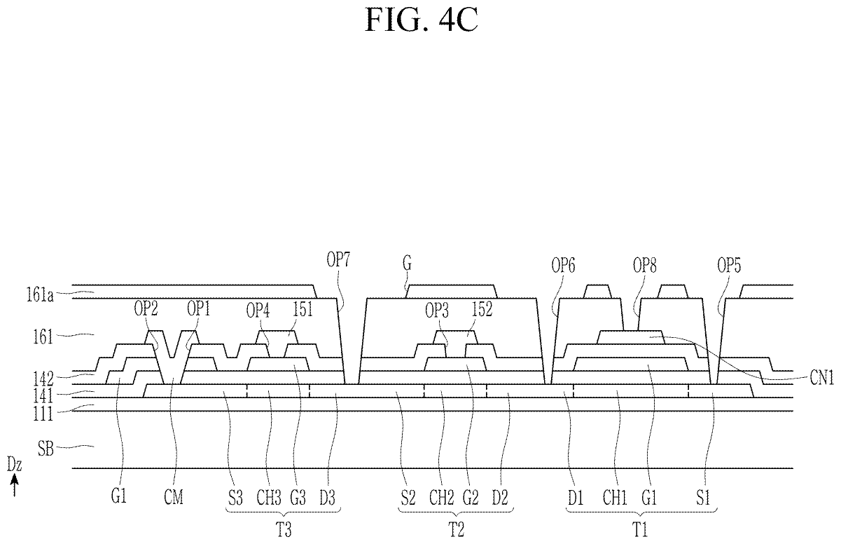

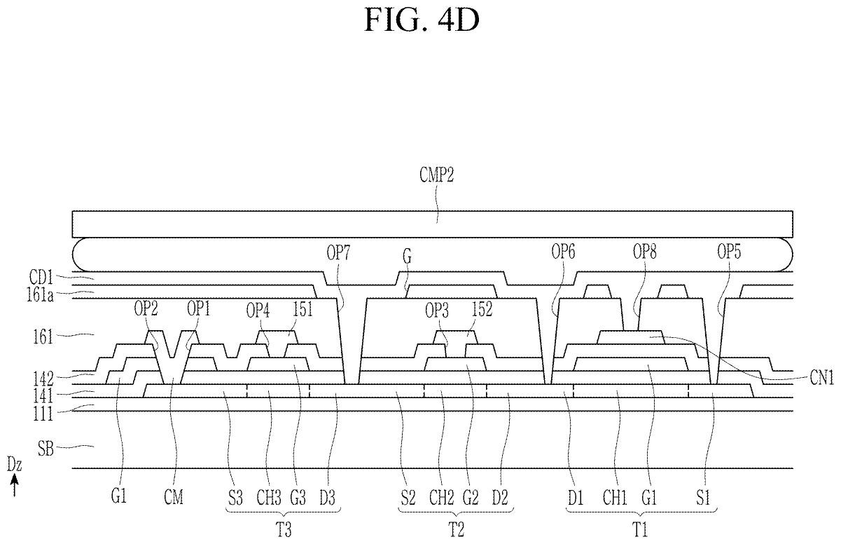

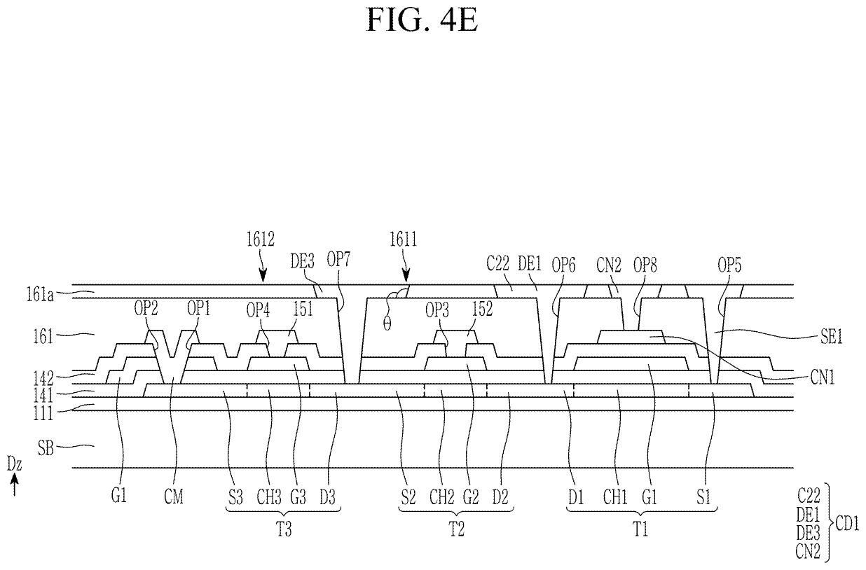

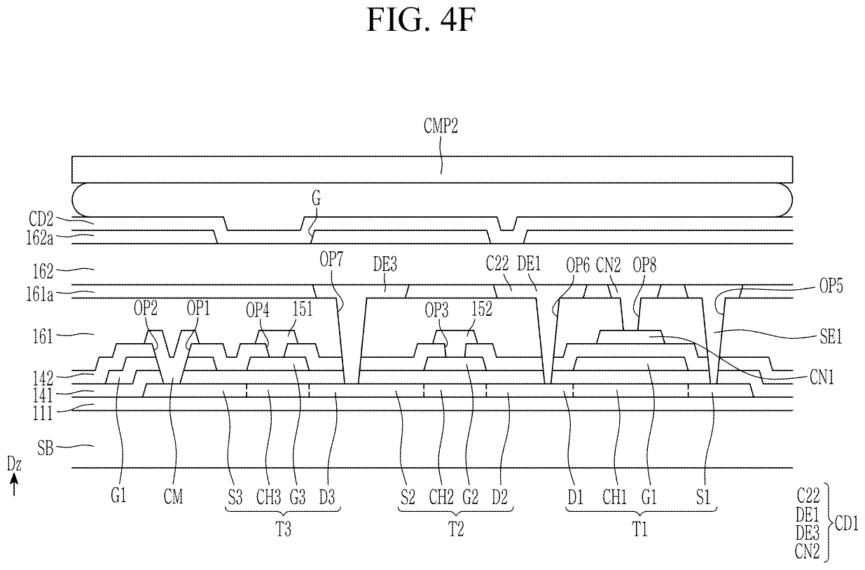

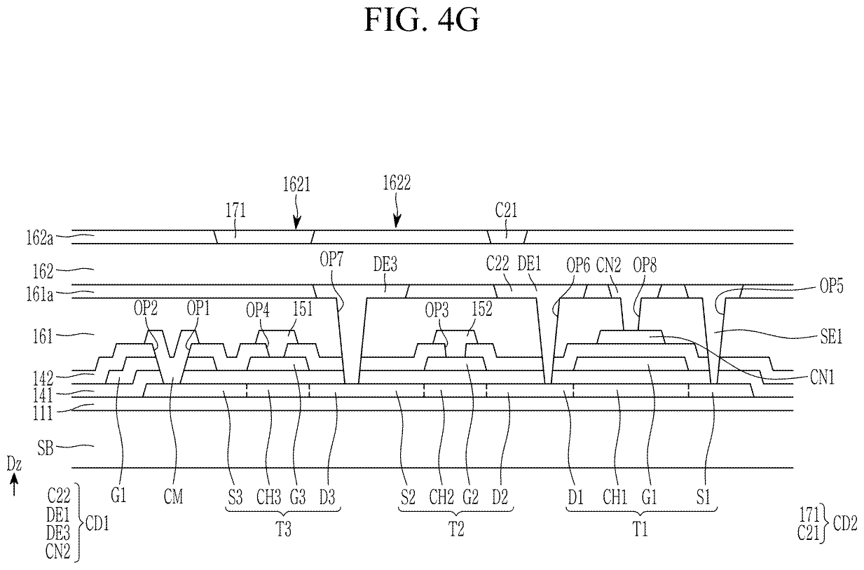

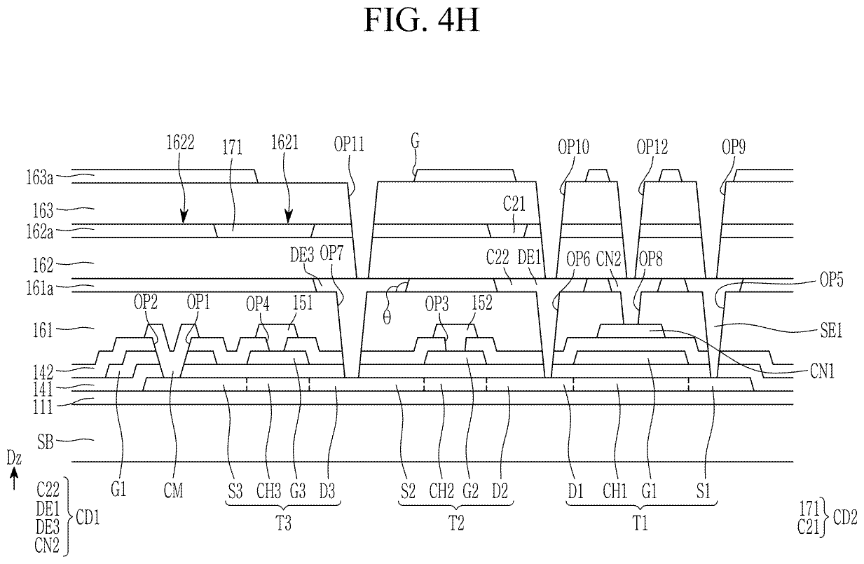

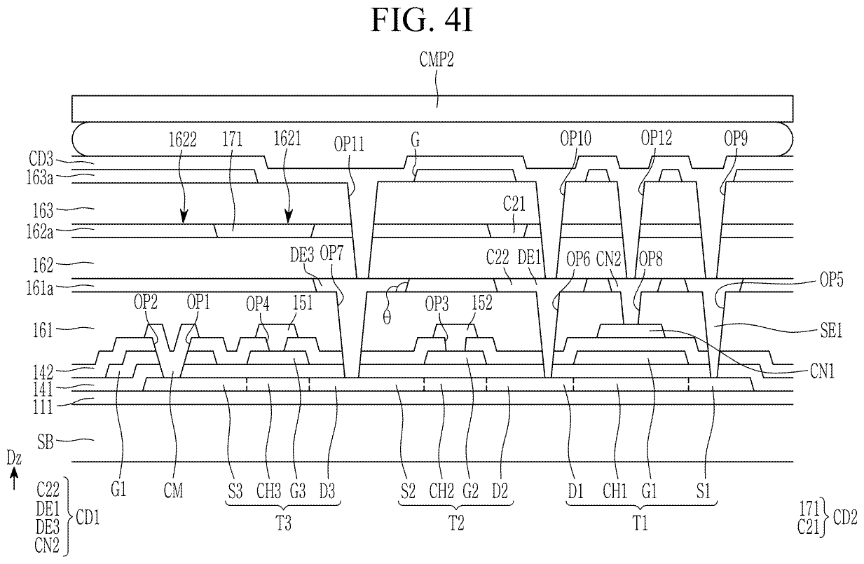

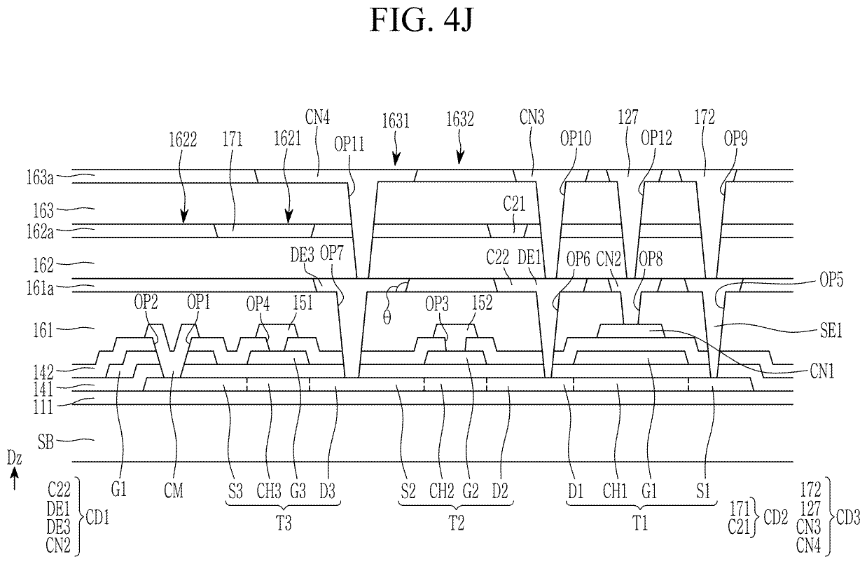

A method of manufacturing a display device according to an embodiment may be described with reference to FIG. 4A to FIG. 4J along with FIG. 3. FIG. 4A to FIG. 4J are cross-sectional views showing a manufacturing method of a display device according to an embodiment.

As shown in FIG. 4A, a buffer layer 111 may be formed on a substrate SB, a semiconductor layer (CH1, CH2, CH3, S1, S2, S3, D1, D2, and D3) may be formed on the buffer layer 111, a gate insulating layer 141 may be formed on the semiconductor layer (CH1, CH2, CH3, S1, S2, S3, D1, D2, and D3), a first gate conductor including a first gate electrode G1, a second gate electrode G2, and a third gate electrode G3 may be formed on the gate insulating layer 141, a second gate insulating layer 142 may be formed on the first gate conductor, a second gate conductor including a first scan line 151, a second scan line 152, a first connection line CN1, and a connecting member CM may be formed on the second gate insulating layer 142, and an insulating layer 160a forming a first interlayer insulating layer 161 may be stacked on the second gate conductor.

The insulating layer 160a may have a different height measured from the substrate surface along the first direction Dz depending on the position. Because the curvature of the metal wirings formed under the insulating layer 160a may be transferred to the insulating layer 160a, and since such curvature may affect the layer formed later, a planarization process may be required to remove the curvature formed on the surface. For this, as shown in FIG. 4A, by polishing the surface of the surface of the insulating layer 160a by using a first planarization process CMP1, as shown in FIG. 4B, the first interlayer insulating layer 161 with the uniform height measured from the substrate surface along the first direction Dz may be formed.

In the shown embodiment, it is described that the first interlayer insulating layer 161 may be formed of one layer, however it is not limited thereto, and the first interlayer insulating layer 161 may be formed of the first layer including a silicon nitride and the second layer including a silicon oxide, while the first layer including a silicon nitride may serve as a stopper in the planarization process of the second layer including a silicon oxide. Accordingly, a portion of the first interlayer insulating layer 161 may have the same height as the height of the surface of the first layer.

Referring to FIG. 4C, a first side wall insulating layer 161a may be formed on the first interlayer insulating layer 161. The first side wall insulating layer 161a may be a layer formed to be polished together during the subsequent polishing of the first data conductor CD1 and may be thinly made of a silicon oxide or a silicon nitride. For example, it may be formed to a thickness of about 5000 Å to 7000 Å, or in another embodiment about 5500 Å to 6500 Å. The first side wall insulating layer 161a may have at least one depressed portion G. The depressed portion G may be formed corresponding to the position where the wiring of the first data conductor CD1 may be formed. In the first interlayer insulating layer 161, the first side wall insulating layer 161a, the second gate insulating layer 142, the first gate insulating layer 141, a fifth contact hole OP5, and a sixth contact hole OP6 exposing the first source region S1 and the first drain region D1 of the first transistor T1, and a seventh contact hole OP7 exposing the third drain region D3 of the third transistor T3 may be formed, and an eighth contact hole OP8 exposing the first connection electrode CN1 may be formed in the second portion 1612 of the first interlayer insulating layer 161.

At this time, when the first interlayer insulating layer 161 and the first side wall insulating layer 161a may be made of different materials, the contact holes may be respectively formed in different widths by different etching ratios, for example, as shown in FIG. 4C, the width of the portion in which the first side wall insulating layer 161a may be positioned in each contact hole may be formed to be larger.

As shown in FIG. 4D, on the first interlayer insulating layer 161 and the first side wall insulating layer 161a, a first data conductor CD1 may be formed to fill the depressed portion G, and the first data conductor CD1 and the first side wall insulating layer 161a may be planarized by the second planarization process CMP2. At this time, the second planarization process CMP2, the first data conductor CD1 and the first side wall insulating layer 161a may be simultaneously planarized by applying the slurry for polishing copper as described above. For example, the first data conductor CD1 may be copper wiring. By using the slurry for polishing copper which may include the catalyst with the single molecule which may include iron ions and the oxidizing agent, the Fenton reaction occurs, and accordingly, the copper oxide film may be formed at a high speed on the surface of the copper wiring, so the polishing of the first data conductor CD1 and the first side wall insulating layer 161a may be completed through one-step polishing without the dishing. Accordingly, as shown in FIG. 4E, the obtained first metal surface 1611 of the first data conductor CD1 and first insulating surface 1612 of the first side wall insulating layer 161a may have the same height from the substrate and may have the polished flat surface. As shown in FIG. 4E, the angle θ between the lower surface and the side surface of the wirings included in the first data conductor CD1 may be formed to be 90 degrees or more, since the first side wall insulating layer 161a may be first formed and patterned and the first data conductor CD1 may be formed as above-described. The first side wall insulating layer 161a may be formed to be disposed between the wirings included in the first data conductor CD1, not on the wirings.

As shown in FIG. 4F, a second interlayer insulating layer 162 may be formed on the first side wall insulating layer 161a and the first data conductor CD1. At this time, since the first insulating surface 1612 and the first metal surface 1611 of the first side wall insulating layer 161a and the first data conductor CD1 of the portion where the second interlayer insulating layer 162 may be formed already have the polished flat surfaces of the same height, the second interlayer insulating layer 162 may be formed without performing an additional planarization process or the like. On the second interlayer insulating layer 162, the second side wall insulating layer 162a may be formed and patterned for the portion where the second data conductor CD2 may be to be formed to form the depressed portion G, and a second data conductor CD2 may be formed on the second interlayer insulating layer 162 and the second side wall insulating layer 162a.

The second data conductor CD2 and the second side wall insulating layer 162a may be planarized by the second planarization process CMP2. At this time, the second planarization process CMP2 may be a process of simultaneously planarizing the second data conductor CD2 and the second side wall insulating layer 162a by applying the slurry for polishing copper, as in the previous first data conductor CD1. For example, the second data conductor CD2 may be the copper wiring. By using the slurry for polishing copper which may include the catalyst with the single molecule which may include iron ions and the oxidizing agent, the Fenton reaction occurs, and accordingly, the copper oxide film may be formed at a high speed on the surface of the copper wiring, so the polishing of the second data conductor CD2 and the first side wall insulating layer 161a may be completed through one-step polishing without the dishing. Accordingly, as shown in FIG. 4G, the data line 171 and the second data conductor CD2 including the first electrode C21 of the second capacitor C2 extended from the data line 171 may be formed. The obtained second metal surface 1621 of the second data conductor CD2 and the first insulating surface 1622 of the second side wall insulating layer 162a may have the same height from the substrate and may have the polished flat surface. Since the second side wall insulating layer 162a may be first formed and patterned and the first data conductor CD2 may be formed as described above, the angle between the lower surface and the side surface of the second data conductor CD2 may also be formed at 90 degrees or more in the same way as the wirings included in the first data conductor CD1. The second side wall insulating layer 162a may be formed to be disposed between the wirings included in the second data conductor CD2, rather than on the wirings.

Subsequently, as shown in FIG. 4H, a third interlayer insulating layer 163 may be formed on the second side wall insulating layer 162a and the second data conductor CD2. Also, at this time, since the second insulating surface 1622 and the second metal surface 1621 of the second side wall insulating layer 162a and the second data conductor CD2 of the portion where the third interlayer insulating layer 163 maybe formed already have the polished flat surfaces of the same height, the third interlayer insulating layer 163 may be formed without performing an additional planarization process or the like.

A third side wall insulating layer 163a may be formed on the third interlayer insulating layer 163. The third side wall insulating layer 163a may have at least one depressed portion G. The depressed portion G may be formed corresponding to the position where the wiring of the third data conductor CD3 may be formed. In the second interlayer insulating layer 162, the third interlayer insulating layer 163 and the third side wall insulating layer 163a, a ninth contact hole OP9 and a tenth contact hole OP10 exposing the first source electrode SE1 and the first drain electrode DE1 of the first transistor T1, an eleventh contact hole OP11 exposing the third drain electrode DE3 of the third transistor T3 may be formed, and a twelfth contact hole OP12 exposing the second connection electrode CN2 may be formed.

At this time, when the third interlayer insulating layer 163 and the third side wall insulating layer 163a may be made of different materials, the contact holes may be respectively formed in different widths by different etching ratios, for example, as shown in FIG. 4H, the width of the portion in which the third side wall insulating layer 163a may be positioned in each contact hole may be formed to be larger.

As shown in FIG. 4I, on the third interlayer insulating layer 163 and the third side wall insulating layer 163a, a third data conductor CD3 may be formed to fill the depressed portion G, and the third data conductor CD3 and the third side wall insulating layer 163a may be planarized by the second planarization process CMP2. At this time, the second planarization process CMP2 simultaneously planarizes the third data conductor CD3 and the third side wall insulating layer 163a by applying the slurry for polishing copper in the same manner as in the previous first data conductor CD1 and the second data conductor CD2. For example, at this time, the third data conductor CD3 may be the copper wiring. By using the slurry for polishing copper which may include the catalyst with the single molecule which may include iron ions and the oxidizing agent, the Fenton reaction occurs, and accordingly, the copper oxide film may be formed at a high speed on the surface of the copper wiring, so the polishing of the third data conductor CD3 and the third side wall insulating layer 163a may be completed through one-step polishing without the dishing. Accordingly, as shown in FIG. 4J, the third data conductor CD3 including the initialization voltage layer 127, the driving voltage line 172, the third connection electrode CN3, and the fourth connection electrode CN4 may be formed. The obtained third metal surface 1631 of the third data conductor CD3 and the third insulating surface 1632 of the third side wall insulating layer 163a may have the same height as the substrate and may have the polished flat surface.

Since the third side wall insulating layer 163a may be first formed and patterned and the third data conductor CD3 may be formed as above-described, similarly to the wirings included in the first data conductor CD1, the angle between the lower surface and the side surface of the wirings included in the third data conductor CD3 may be formed to be 90 degrees or more. The side wall insulating layer 163a may be formed to be disposed between the wirings included in the third data conductor CD3, not on the wirings.

An insulating layer 180 may be formed on the third data conductor CD3 and the third side wall insulating layer 163a, a pixel electrode 191 may be formed on the insulating layer 180, a pixel definition layer 350 may be formed on the pixel electrode 191, an emission layer 370 may be formed within the pixel opening 3405 of the pixel definition layer 350, and a common electrode 270 may be formed on the emission layer 370 and the pixel definition layer 350, thereby forming the display device shown in FIG. 3.

As such, according to the manufacturing method of the display device according to the embodiment, when polishing the first data conductor CD1, the second data conductor CD2, and the third data conductor CD3 forming the metal wiring, it may be possible to polish together with the insulating layers in only one step by using the slurry for polishing copper which may include the catalyst which may include the single molecule with iron ions and the oxidizing agent. Accordingly, it may be possible to prevent the dishing from occurring on the surface while simplifying the manufacturing process, and, at the same time, the surface of the subsequently formed layer may be formed to be planarized without an additional process. Even if multiple wirings may be stacked, it may be possible to form the device without increasing the thickness of the entire device, so that it may be possible to form a high-step-difference stacked structure of high-resolution. In an embodiment, it may be described that the first data conductor CD1, the second data conductor CD2, and the third data conductor CD3 may be all made of copper wiring and may be manufactured by applying the slurry for polishing copper, but embodiments are not limited thereto, and of course, it may also be possible to be applied to one or more of these, so it may not be limited to the configuration described in the embodiment.

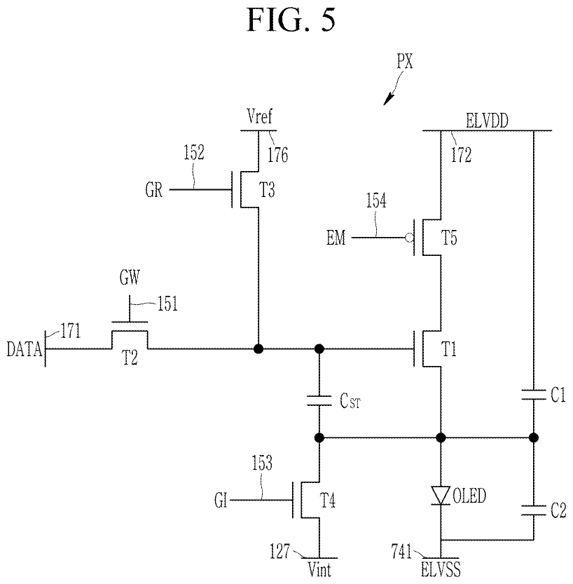

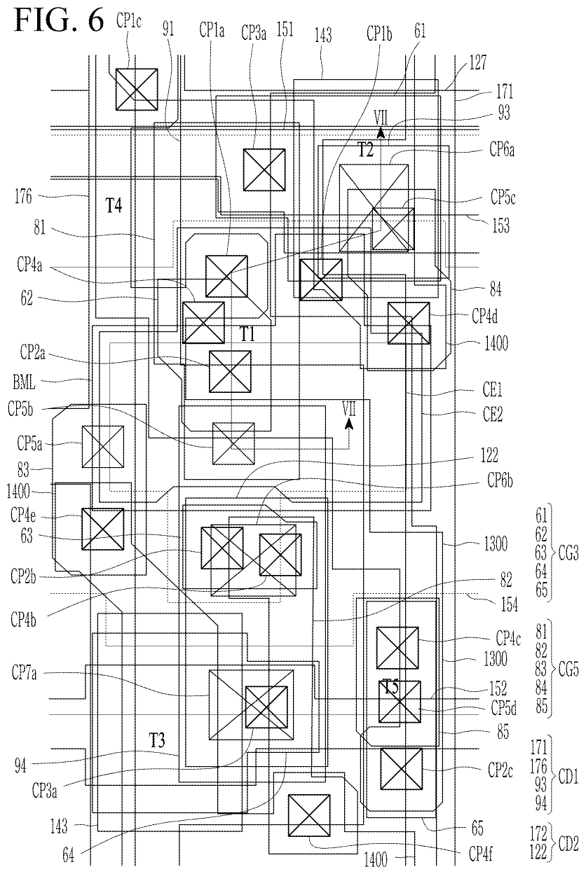

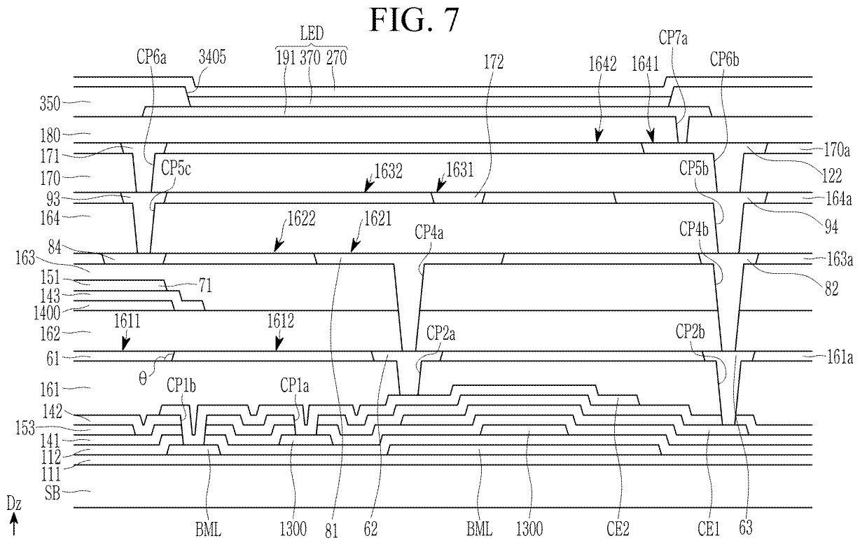

A display device according to another embodiment may be described with reference to FIG. 5 to FIG. 7. FIG. 5 is a schematic diagram of an equivalent circuit of a pixel of a display device according to another embodiment, FIG. 6 is a schematic layout view of one pixel of a display device according to another embodiment, and FIG. 7 is a schematic cross-sectional view taken along a line VII-VII of FIG. 6.

Referring to FIG. 5, one pixel PX of the display device according to another embodiment may include signal lines 151, 152, 153, 154, 127, 171, 172, and 176, and transistors T1, T2, T3, T4, and T5, a storage capacitor Cst, a first capacitor C1 and a second capacitor C2, and an organic light emitting diode OLED, which may be connected thereto.

The signal lines may include a data line 171, a driving voltage line 172, a reference voltage layer 176, an initialization voltage layer 127, a first scan line 151, a second scan line 152, an initialization control line 153, and a light emission control line 154.

The data line 171 may be a wire for transmitting a data voltage DATA generated from the data driver (not shown), and luminance emitted from the organic light emitting diode OLED changes according to the data voltage DATA applied to the pixel PX.

The driving voltage line 172 applies a driving voltage ELVDD, the reference voltage line 176 transmits a reference voltage Vref, the initialization voltage line 127 transmits an initialization voltage Vint for initializing a second storage electrode of the storage capacitor Cst, a second electrode of the driving transistor T1, and an anode of the organic light emitting diode OLED, and the common voltage line 741 applies a common voltage ELVSS to a cathode of the organic light emitting diode OLED. The voltage applied to the driving voltage line 172, the initialization voltage line 127, and the common voltage line 741 may be a constant voltage, respectively.

The transistors T1, T2, T3, T4, and T5 are described. The transistors T1, T2, T3, T4, and T5 may include a driving transistor T1 (referred to as a first transistor), a second transistor T2, a third transistor T3, a fourth transistor T4, and a fifth transistor T5.

The driving transistor T1 includes a gate electrode connected to a first storage electrode of the storage capacitor Cst, a first electrode connected to a second electrode of the fifth transistor T5, and a second electrode connected to the anode of the organic light emitting diode OLED. The gate electrode of the driving transistor T1 may also be connected to the second electrode second transistor T2 and the second electrode of the third transistor T3. The second electrode of the driving transistor T1 may also be connected to the second electrode of the fourth transistor T4 and the second storage electrode of the storage capacitor Cst. The second electrode of the driving transistor T1 may also be connected to the second electrode of the fourth transistor T4 and the second storage electrode of the storage capacitor Cst. The first electrode of the driving transistor T1 may be connected to the driving voltage line 172 via the fifth transistor T5.

The second transistor T2 includes a gate electrode connected to the gate line 121, a first electrode connected to the data line 171, and a second electrode connected to the gate electrode of the driving transistor T1. The second electrode of the second transistor T2 may also be connected to the second electrode of the third transistor T3 and the first storage electrode of the storage capacitor Cst. The second transistor T2 has an n-type transistor characteristic, and may be turned on when a gate signal GWn of a high voltage is applied to the gate electrode. When the second transistor T2 is turned on, the data voltage DATA supplied through the data line 171 may be transferred to the first storage electrode of the storage capacitor Cst and the gate electrode of the driving transistor T1.

The third transistor T3 includes a gate electrode connected to the voltage control line 152, a first electrode connected to the reference voltage line 176, and a second electrode connected to the gate electrode of the driving transistor T1. The second electrode of the third transistor T3 may also be connected to the second electrode of the second transistor T2 and the first storage electrode of the storage capacitor Cst. The third transistor T3 has the n-type transistor characteristic, and may be turned on when a voltage control signal GRn of a high voltage is applied to the gate electrode. When the third transistor T3 is turned on, the reference voltage Vref from the reference voltage line 176 may be transferred to the first storage electrode of the storage capacitor Cst and the gate electrode of the driving transistor T1.

The fourth transistor T4 includes a gate electrode connected to the initialization control line 153, a first electrode connected to the initialization voltage line 127, and a second electrode connected to the second storage electrode of the storage capacitor Cst. The second electrode of the fourth transistor T4 may also be connected to the second electrode of the driving transistor T1 and the anode of the organic light emitting diode OLED. The fourth transistor T4 has the n-type transistor characteristic, and may be turned on when an initialization control signal Gin of a high voltage is applied to the gate electrode. When the fourth transistor T4 is turned on, the initialization voltage Vint from the initialization voltage line 127 may be transferred to the second storage electrode of the storage capacitor Cst, the anode of the organic light emitting diode OLED, and the second electrode of the driving transistor T1.

The fifth transistor T5 includes a gate electrode connected to the light emitting control line 154, a first electrode connected to the driving voltage line 172, and a second electrode connected to the first electrode of the driving transistor T1. The fifth transistor T5 has a p-type transistor characteristic, and may be turned on when a light emitting control signal EMn of a low voltage is applied to the gate electrode. When the fifth transistor T5 is turned on, the driving voltage ELVDD from the driving voltage line 172 may be transferred to the first electrode of the driving transistor T1.

Some transistors among the transistors T1, T2, T3, T4, and T5 included in the pixel PX have the n-type transistor characteristic in which the semiconductor layer may be formed as an oxide semiconductor, and the remaining transistors have the p-type transistor characteristic in which the semiconductor layer may be formed as a polycrystalline semiconductor. Hereinafter, the transistor including the oxide semiconductor may be referred to as an oxide semiconductor transistor, and the transistor including the polycrystalline semiconductor may be referred to as a polycrystalline semiconductor transistor.

The storage capacitor Cst may include the first electrode connected to the gate electrode of the driving transistor T1 and the second electrode connected to the second electrode of the first transistor T4. The first storage electrode of the storage capacitor Cst may also be connected to the second electrode of the second transistor T2 and the second electrode of the third transistor T3. The storage capacitor Cst may store the data voltage DATA supplied through the second transistor T2. The data voltage DATA stored in the storage capacitor Cst adjusts the degree to which the driving transistor T1 turns on to determine the magnitude of the driving current.

The first capacitor C1 may include a first electrode connected to the driving voltage ELVDD and a second electrode connected to the second electrode of the driving transistor T1, and the second capacitor C2 may include a first electrode connected to the second electrode of the driving transistor T1 and a second electrode connected to the common voltage ELVSS.

The organic light emitting diode OLED may include the anode connected to the second electrode of the driving transistor T1 and the cathode to which the common voltage may be applied. The organic light emitting diode OLED emits light according to the driving current output from the driving transistor T1 to express a gray.

An example of one pixel shown in FIG. 5 is described with reference to FIG. 6 and FIG. 7.

Referring to FIG. 6 and FIG. 7, a buffer layer 111 may be formed on a substrate SB. A metal layer BML may be positioned on the buffer layer 111.

A first buffer layer 112 may be positioned on the metal layer BML.

A first semiconductor layer 1300 may be positioned on the first buffer layer 112.

The first semiconductor layer 1300 may include a polycrystalline semiconductor.

The portion of the first semiconductor layer 1300 may overlap the metal layer BML.

A first gate insulating layer 141 may be positioned on the first semiconductor layer 1300.

A first gate conductor including an initialization control line 153, a light emission control line 154, and a first capacitor electrode CE1 may be positioned on the first gate insulating layer 141.

A second gate insulating layer 142 may be positioned on the first gate conductor.

A first contact hole CP1a exposing one portion of the first semiconductor layer 1300 may be formed in the second gate insulating layer 142 and the first gate insulating layer 141, and a second contact hole CP1b exposing one portion of the metal layer BML may be formed in the second gate insulating layer 142, the first gate insulating layer 141, and the first buffer layer 112. A third contact hole CP1c exposing another portion of the first semiconductor layer 1300 may be formed in the second gate insulating layer 142 and the first gate insulating layer 141.

A second gate conductor including a first initialization voltage layer 127 and a second capacitor electrode CE2 may be positioned on the second gate insulating layer 142.

The second capacitor electrode CE2 may connect the metal layer BML and the first semiconductor layer 1300 through the first contact hole CP1a and the second contact hole CP1b.

The first capacitor electrode CE1 and the second capacitor electrode CE2 may form a capacitor.

A first interlayer insulating layer 161 and a first side wall insulating layer 161a may be positioned. The first interlayer insulating layer 161 may have a constant height measured from the substrate surface along the first direction Dz. For example, the surface of the first interlayer insulating layer 161 may be flat. The first interlayer insulating layer 161 may include a silicon nitride, a silicon oxide, a silicon oxynitride, or the like. The first interlayer insulating layer 161 may be formed of a multilayer in which a layer including a silicon nitride and a layer including a silicon oxide may be stacked. For example, in the illustrated embodiment, the first interlayer insulating layer 161 is illustrated as being composed of one layer, but the disclosure is not limited thereto, and the first interlayer insulating layer 161 may be formed of a first layer including a silicon nitride and a second layer including a silicon oxide, and the first layer including a silicon nitride may serve as a stopper in the planarization process of the second layer including a silicon oxide. Accordingly, the portion of the first interlayer insulating layer 161 may have the same height as the height of the surface of the first layer.

On the first interlayer insulating layer 161, a first side wall insulating layer 161a may be positioned. The first side wall insulating layer 161a may be made of a silicon oxide or a silicon nitride. In the polishing process after formation of the metal wiring to be described later, it may be polished in the same process as the metal wiring (the conductor).

The first interlayer insulating layer 161 and the first side wall insulating layer 161a may have a fourth contact hole CP2a exposing the second capacitor electrode CE2, and the first interlayer insulating layer 161, the first side wall insulating layer 161a and the second gate insulating layer 142 may have a fifth contact hole CP2b exposing the first capacitor electrode CE1, and the first interlayer insulating layer 161, the first side wall insulating layer 161a, the second gate insulating layer 142, and the first gate insulating layer 141 may have a sixth contact hole CP2c exposing another portion of the first semiconductor layer 1300. The size of each contact hole may be formed to be larger in the portion corresponding to the first side wall insulating layer 161a. In FIG. 6, although the first side wall insulating layer 161a is not shown, since the layout thereof may be the same as that of the first interlayer insulating layer 161 in a plane view, and only the size of the contact hole may be slightly different, the display of the first side wall insulating layer 161a is omitted in FIG. 6 showing the arrangement on a plane. The following other side wall insulating layers may be also the same.

A third gate conductor CG3 which may include a first connection portion 61, a second connection portion 62, a third connection portion 63, a fourth connection portion 64, and a fifth connection portion 65 may be formed on the first interlayer insulating layer 161. The third gate conductor CG3 includes copper. Therefore, the slurry for polishing copper described above may be applied.

The second connection portion 62 may be connected to the second capacitor electrode CE2 through the fourth contact hole CP2a, and the third connection portion 63 may be connected to the first capacitor electrode CE1 through the fifth contact hole CP2b. The fifth connection portion 65 may be connected to one portion of the first semiconductor 1300 through the sixth contact hole CP2c.

According to the display device according to an embodiment, the first side wall insulating layer 161a may be polished together with the metal wiring (the conductor) in the polishing process after the formation of the metal wiring. For example, when the third gate conductor CG3 which may include the first connection portion 61, the second connection portion 62, the third connection portion 63, the fourth connection portion 64, and the fifth connection portion 65 may be formed and the polishing process may be performed thereon, and the third gate conductor CG3 made of the metal (for example, copper) and the first side wall insulating layer 161a may be polished together in one process by using the polishing slurry described above. Accordingly, the first metal surface 1611 of the wirings (i.e., the first connection portion 61, the second connection portion 62, the third connection portion 63, the fourth connection portion 64, and the fifth connection portion 65) included in the third gate conductor CG3 and the first insulating surface 1612 of the first side wall insulating layer 161a may have the same height and may all include the polished surface. Here, the surface height of each layer may be the height measured from the substrate surface along the first direction Dz. As described above, since the surface height of the third gate conductor CG3 and the first side wall insulating layer 161a may be the same, the subsequent process may be performed without an additional planarization process.

The angle θ formed between the lower surface of the third gate conductor CG3 and the side surface of the third gate conductor CG3 may be 90 degrees or more. For example, the lower surface of the third gate conductor CG3 and the side surface of the third gate conductor CG3 meet each other while forming the obtuse angle. This, like the later-described manufacturing method, may be the shape that appears because the first side wall insulating layer 161a may be first formed and etched to prepare the portion where the third gate conductor CG3 may be formed, and the excess metal and the first side wall insulating layer 161a may be polished together. On the other hand, in the process of forming the wiring using the conductor first, forming an insulating layer to cover it, and etching the insulating layer to expose the wiring, since the wiring may be patterned first, the side surface and the lower surface of the wiring form an acute angle. As described above, in the configuration according to the embodiment in which the lower surface of the first data conductor CD1 and the side surface of the third gate conductor CG3 form the obtuse angle with each other, the area of the upper surface exposed upward may be formed to be wider, so that a degree of freedom may be further increased in the connection with the upper conductors in a subsequent process.

A second interlayer insulating layer 162 may be positioned on the third gate conductor CG3. The height of the second interlayer insulating layer 162 measured from the substrate surface along the first direction Dz may be constant. For example, the surface of the first interlayer insulating layer 161 may be planarized. As described above, since the surface heights of the third gate conductor CG3 disposed under the second interlayer insulating layer 162 and the first side wall insulating layer 161a may be the same, the second interlayer insulating layer 162 of which the surface height may be constant even without an additional planarization process for the second interlayer insulating layer 162 may be obtained. The second interlayer insulating layer 162 may include an insulating material, and for example, the second interlayer insulating layer 162 may include a silicon oxide.

A second semiconductor layer 1400 may be positioned on the second interlayer insulating layer 162.

A third gate insulating layer 143 may be positioned on the second semiconductor layer 1400. The third gate insulating layer 143 may be formed to cover a portion of the second semiconductor layer 1400.

A fourth gate conductor including a second scan line 152 and an initialization control line 153 may be positioned on the third gate insulating layer 143.

A third interlayer insulating layer 163 may be positioned on the fourth gate conductor. The third interlayer insulating layer 163 may have a constant height measured from the substrate surface along the first direction Dz. For example, the surface of the third interlayer insulating layer 163 may be planarized. The third interlayer insulating layer 163 may include a silicon nitride, a silicon oxide, a silicon oxynitride, or the like. The first interlayer insulating layer 163 may be formed of a multilayer in which a layer may include a silicon nitride and a layer may include a silicon oxide may be stacked. For example, in the illustrated embodiment, the third interlayer insulating layer 163 is illustrated as being composed of one layer, but the embodiments are not limited thereto, and the first interlayer insulating layer 161 may be formed of a first layer which may include a silicon nitride and a second layer which may include a silicon oxide. The first layer which may include a silicon nitride may serve as a stopper in the planarization process of the second layer which may include a silicon oxide. Accordingly, the portion of the third interlayer insulating layer 163 may have the same height as the height of the surface of the first layer.

A third side wall insulating layer 163a may be positioned on the third interlayer insulating layer 163. The third side wall insulating layer 163a may be formed of a silicon oxide or a silicon nitride. In the polishing process after a formation of a metal wiring to be described later, it may be polished in the same process as the metal wiring (a conductor).

The third interlayer insulating layer 163, the third side wall insulating layer 163a, and the second interlayer insulating layer 162 may have a seventh contact hole CP4a, an eighth contact hole CP4b, and a ninth contact hole CP4c exposing the second connection portion 62, the third connection portion 63, and the fifth connection portion 65.

Also, in the third interlayer insulating layer 163 and the third side wall insulating layer 163a and the third gate insulating layer 143, a tenth contact hole CP4d, an eleventh contact hole CP4e, and a twelfth contact hole CP4f exposing a portion of the second semiconductor layer 1400 may be formed. The size of each contact hole may be formed to be larger in the portion corresponding to the third side wall insulating layer 163a.

On the third interlayer insulating layer 163, a fifth gate conductor CG5 including a sixth connection portion 81, a seventh connection portion 82, an eighth connection portion 83, a ninth connection portion 84, and a tenth connection portion 85 may be positioned. The fifth gate conductor CG5 includes copper. Therefore, the slurry for polishing copper described above may be applied.

The sixth connection portion 81 may be connected to the second connection portion 62 through the seventh contact hole CP4a, the seventh connection portion 82 may be connected to the third connection portion 63 through the eighth contact hole CP4b, and the tenth connection portion 85 may be connected to the fifth connection portion 65 through the ninth contact hole CP4c.

According to the display device according to the embodiment, the third side wall insulating layer 163a may be polished together with the metal wiring (the conductor) in the polishing process after the formation of the metal wiring. For example, when the fifth gate conductor CG5 including the sixth connection portion 81, the seventh connection portion 82, the eighth connection portion 83, the ninth connection portion 84, and the tenth connection portion 85 may be formed and the polishing process may be performed thereon, the fifth gate conductor CG5 made of the metal (for example, copper) and the third side wall insulating layer 163a may be polished together in one process by using the polishing slurry described above. Accordingly, the second metal surface 1621 of the wirings (i.e., the sixth connection portion 81, the seventh connection portion 82, the eighth connection portion 83, the ninth connection portion 84, and the tenth connection portion 85) included in the fifth gate conductor CG5 and the second insulating surface 1622 of the third side wall insulating layer 163a may have the same height and all include the polished surface. Here, the surface height of each layer may be the height measured from the substrate surface along the first direction Dz. As described above, since the surface height of the fifth gate conductor CG5 and the third side wall insulating layer 163a may be the same, the subsequent process may be performed without an additional planarization process.

The angle θ formed between the lower surface of the fifth gate conductor CG5 and the side surface of the fifth gate conductor CG5 may be 90 degrees or more. For example, the lower surface of the fifth gate conductor CG5 and the side surface of the fifth gate conductor CG5 meet each other while forming the obtuse angle. This, like the later-described manufacturing method, may be the shape that appears because the third side wall insulating layer 163a may be first formed and etched to prepare the portion where the fifth gate conductor CG5 may be formed, and the excess metal and the third side wall insulating layer 163a may be polished together. On the other hand, in the process of forming the wiring using the conductor first, forming an insulating layer to cover it, and etching the insulating layer to expose the wiring, since the wiring may be patterned first, the side surface and the lower surface of the wiring form an acute angle. As described above, in the configuration according to the embodiment in which the lower surface of the fifth gate conductor CG5 and the side surface of the fifth gate conductor CG5 form the obtuse angle with each other, the area of the upper surface exposed upward may be formed to be wider, so that a degree of freedom may be further increased in the connection with the upper conductors in a subsequent process.

The seventh connection portion 82 may be connected to one portion of the second semiconductor layer 1400 through the twelfth contact hole CP4f, and the ninth connection portion 84 may be connected to one portion of the second semiconductor layer 1400 through the tenth contact hole CP4d.

A fourth interlayer insulating layer 164 may be positioned on the fifth gate conductor CG5. The fourth interlayer insulating layer 164 may have a constant height measured from the substrate surface along the first direction Dz. For example, the surface of the fourth interlayer insulating layer 164 may be planarized. As described above, since the surface heights of the fifth gate conductor CG5 disposed under the fourth interlayer insulating layer 164 and the third side wall insulating layer 163a may be the same, the fourth interlayer insulating layer 164 of which the surface height may be constant even without an additional planarization process for the fourth interlayer insulating layer 164 may be obtained. The fourth interlayer insulating layer 164 may include an insulating material, and for example, the fourth interlayer insulating layer 164 may include a silicon oxide.

A fourth side wall insulating layer 164a may be positioned on the fourth interlayer insulating layer 164. The fourth side wall insulating layer 164a may be made of a silicon oxide or a silicon nitride. In the polishing process after formation of the metal wiring to be described later, it may be polished in the same process as the metal wiring (conductor).

In the fourth interlayer insulating layer 164 and the fourth side wall insulating layer 164a, a thirteenth contact hole CP5a exposing the eighth connection portion 83, a fourteenth contact hole CP5b exposing the sixth connection portion 82, a fifteenth contact hole CP5c exposing the ninth connection portion 84, and a sixteenth contact hole CP5d exposing the tenth connection portion 85 may be formed.

A first data conductor CD1 including a driving voltage line 172, a reference voltage layer 176, an eleventh connection portion 93, and a twelfth connection portion 94 may be positioned on the fourth interlayer insulating layer 164. The first data conductor CD1 includes copper. Therefore, the slurry for polishing copper described above may be applied.

The eighth connection portion 83 may be connected to the reference voltage layer 176 through the thirteenth contact hole CP5a, the sixth connection portion 82 may be connected to the twelfth connection portion 94 through the fourteenth contact hole CP5b, the ninth connection portion 84 may be connected to the eleventh connection portion 93 through the fifteenth contact hole CP5c, and the tenth connection portion 85 may be connected to the driving voltage line 172 through the sixteenth contact hole CP5d.

According to the display device according to the embodiment, the fourth side wall insulating layer 164a may be polished together with the metal wiring (the conductor) in the polishing process after the metal wiring may be formed. For example, when the first data conductor CD1 including the driving voltage line 172, the reference voltage layer 176, the eleventh connection portion 93, and the twelfth connection portion 94 may be formed and the polishing process may be performed thereon, by using the polishing slurry described above, the first data conductor CD1 made of the metal (for example, copper) and the fourth side wall insulating layer 164a may be polished together in one process. Accordingly, the third metal surface 1631 of the wirings (i.e., the driving voltage line 172, the reference voltage layer 176, the eleventh connection portion 93, and the twelfth connection portion 94) included in the first data conductor CD1 and the third insulating surface 1632 of the fourth side wall insulating layer 164a may have the same height, and they all may have a polished surface. Here, the surface height of each layer may be the height measured from the substrate surface along the first direction Dz. As described above, since the surface heights of the first data conductor CD1 and the fourth side wall insulating layer 164a may be the same, a subsequent process may be performed without an additional planarization process.

The angle θ formed between the lower surface of the first data conductor CD1 and the side surface of the first data conductor CD1 may be 90 degrees or more. For example, the lower surface of the first data conductor CD1 and the side surface of the first data conductor CD1 meet while forming an obtuse angle. This, like the later-described manufacturing method, may be the shape that appears because the fourth side wall insulating layer 164a may be first formed and etched to prepare the portion where the first data conductor CD1 may be formed, and the excess metal and the fourth side wall insulating layer 164a may be polished together. On the other hand, in the process of forming the wiring using the conductor first, forming an insulating layer to cover it, and etching the insulating layer to expose the wiring, since the wiring may be patterned first, the side surface and the lower surface of the wiring form an acute angle. As described above, in the configuration according to the embodiment in which the lower surface of the first data conductor CD1 and the side surface of the first data conductor CD1 form the obtuse angle with each other, the area of the upper surface exposed upward may be formed to be wider, so that a degree of freedom may be further increased in the connection with the upper conductors in a subsequent process.

A first insulating layer 170 may be positioned on the first data conductor CD1. The first insulating layer 170 may have a constant height measured from the substrate surface along the first direction Dz. For example, the surface of the first insulating layer 170 may be planarized. As described above, since the surface heights of the first data conductor CD1 disposed under the first insulating layer 170 and the fourth side wall insulating layer 164a may be the same, the first insulating layer 170 of which the surface height may be constant even without an additional planarization process for the first insulating layer 170 may be obtained. The first insulating layer 170 may include an insulating material, and for example, the first insulating layer 170 may include a silicon oxide.

On the first insulating layer 170, the first side wall insulating layer 170a may be positioned. The first side wall insulating layer 170a may be formed of a silicon oxide or a silicon nitride. In the polishing process after the formation of the metal wiring to be described later, it may be polished in the same process as the metal wiring (the conductor).

The first insulating layer 170 and the first side wall insulating layer 170a may have a seventeenth contact hole CP6a and an eighteenth contact hole CP6b exposing the eleventh connection portion 93 and the twelfth connection portion 94.

A second data conductor CD2 including a data line 171 and a thirteenth connection portion 122 may be positioned on the first insulating layer 170. The second data conductor CD2 includes copper. Therefore, the slurry for polishing copper described above may be applied.

The eleventh connection portion 93 may be connected to the data line 171 through the seventeenth contact hole CP6a, and the eleventh connection portion 94 may be connected to the thirteenth connection portion 122 through the eighteenth contact hole CP6b.

According to the display device according to the embodiment, the first side wall insulating layer 170a may be polished together with the metal wiring (the conductor) in the polishing process after the formation of the metal wiring. For example, when the second data conductor CD2 including the data line 171 and the thirteenth connection portion 122 may be formed and the polishing process may be performed thereon, the second data conductor CD2 of the metal (for example, copper) and the first side wall insulating layer 170a may be polished together in one process by using the polishing slurry described above. Accordingly, the fourth metal surface 1641 of the wirings (i.e., the data line 171 and the thirteenth connection portion 122) included in the second data conductor CD2 and the fourth insulating surface 1642 of the first side wall insulating layer 170a have the same height, and they all have the polished surface. Here, the surface height of each layer may be the height measured from the substrate surface along the first direction Dz. As described above, since the surface heights of the first data conductor CD1 and the first side wall insulating layer 170a may be the same, the subsequent process may be performed without an additional planarization process.

An angle between the lower surface of the second data conductor CD2 and the side surface of the second data conductor CD2 may be 90 degrees or more. For example, the lower surface of the second data conductor CD2 and the side surface of the second data conductor CD2 meet while forming an obtuse angle. This, like the later-described manufacturing method, may be the shape that appears because the first side wall insulating layer 170a may be first formed and etched to prepare the portion where the second data conductor CD2 may be formed, and the excess metal and the first side wall insulating layer 170a may be polished together. On the other hand, in the process of forming the wiring using the conductor first, forming an insulating layer to cover it, and etching the insulating layer to expose the wiring, since the wiring may be patterned first, the side surface and the lower surface of the wiring form an acute angle. As described above, in the configuration according to the embodiment in which the lower surface of the second data conductor CD2 and the side surface of the second data conductor CD2 form the obtuse angle with each other, the area of the upper surface exposed upward may be formed to be wider, so that a degree of freedom may be further increased in the connection with the upper conductors in a subsequent process.

A second insulating layer 180 may be positioned on the second data conductor CD2, and a nineteenth contact hole CP7a exposing the twelfth connection portion 94 may be formed in the second insulating layer 180. The second insulating layer 180 may have a constant height measured from the substrate surface along the first direction Dz. For example, the surface of the second insulating layer 180 may be planarized. As described above, since the surface heights of the second data conductor CD2 disposed under the second insulating layer 180 and the first insulating layer 170 may be the same, the second insulating layer 180 of which the surface height may be constant even without an additional planarization process for the second insulating layer 180 may be obtained.

A pixel electrode 191 may be formed on the second insulating layer 180, and the pixel electrode 191 may be connected to the thirteenth connection portion 122 through the nineteenth contact hole CP7a and may be connected to the drain electrode of the first transistor T1.

The pixel opening 3405 may be formed in the pixel definition layer 350, and the pixel opening 3405 of the pixel definition layer 350 may overlap the pixel electrode 191. The emission layer 370 may be positioned within the pixel opening 3405 of the pixel definition layer 350.

A common electrode 270 may be positioned on the emission layer 370 and the pixel definition layer 350.

The pixel electrode 191, the emission layer 370, and the common electrode 270 may form the light emitting diode LED. Here, the pixel electrode 191 may be an anode that may be a hole injection electrode, and the common electrode 270 may be a cathode that may be an electron injection electrode. However, an embodiment is not limited thereto, and depending on the driving method of the organic light emitting device, the pixel electrode 191 may be a cathode and the common electrode 270 may be an anode.

Holes and electrons may be respectively injected into the emission layer 370 from the pixel electrode 191 and the common electrode 270, and light may be emitted when an exciton in which the injected holes and electrons may be combined falls from an excited state to a ground state.

Although not shown, an encapsulation layer (not shown) may be positioned on the common electrode 270, and the encapsulation layer may cover the side surface as well as the upper surface of the pixel to seal the pixel part. The encapsulation layer may include multiple layers, and among them, may be formed as a composite film including both an inorganic film and an organic film.

As above-described, according to the display device according to an embodiment, the third gate conductor CG3, the fifth gate conductor CG5, the first data conductor CD1, and the second data conductor CD2 forming the metal wiring respectively have the same height as the surface of the first side wall insulating layer 161a, the third side wall insulating layer 163a, the fourth side wall insulating layer 164a, and the first side wall insulating layer 170a as the insulating layer, thereby the conductor and the insulating layer may be formed to have the planarized surface. Accordingly, the surface of the subsequently formed layer may be formed flat without an additional process, and even when multiple wirings may be stacked, it may be possible to form them without increasing the thickness of the entire device, thereby forming a high resolution high-step stacked structure. In an embodiment, it is described that the third gate conductor CG3, the fifth gate conductor CG5, the first data conductor CD1, and the second data conductor CD2 may be all formed of copper and the slurry for polishing copper is applied, however the disclosure is not limited thereto, and it is of course also possible to apply the slurry for polishing copper to one or more of them, and is not limited to the configuration described in an embodiment.

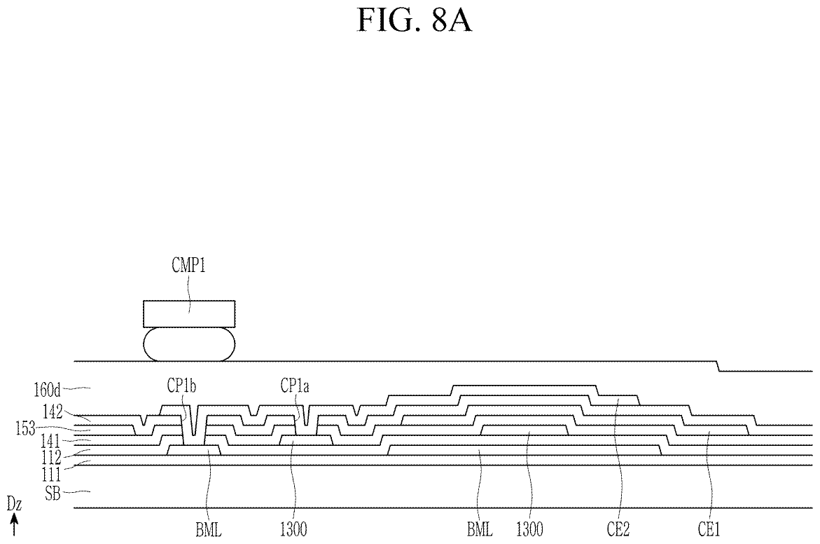

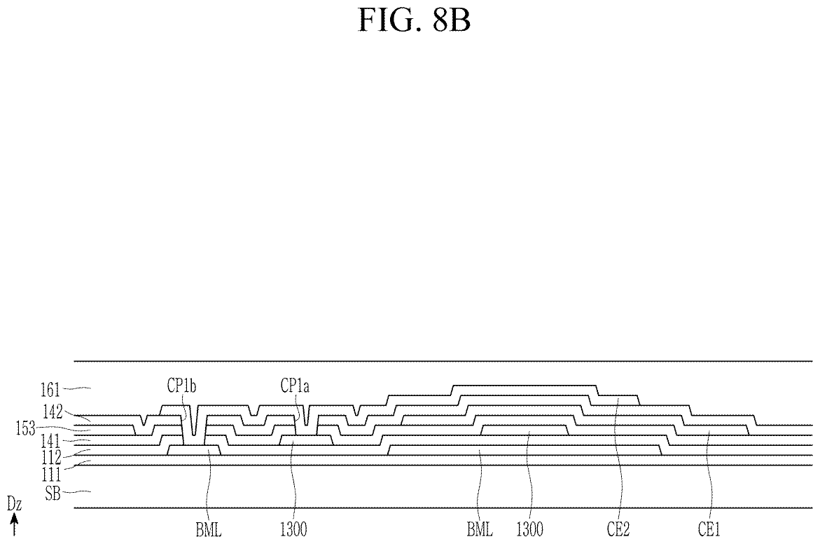

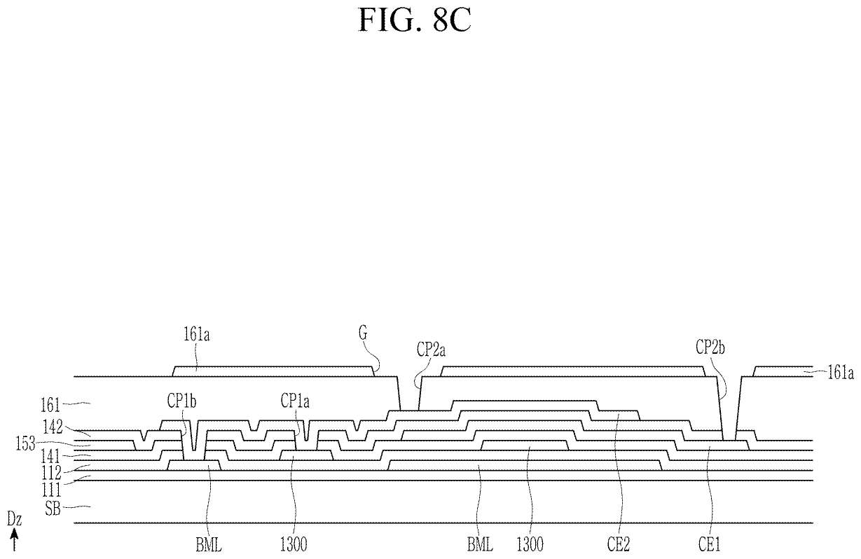

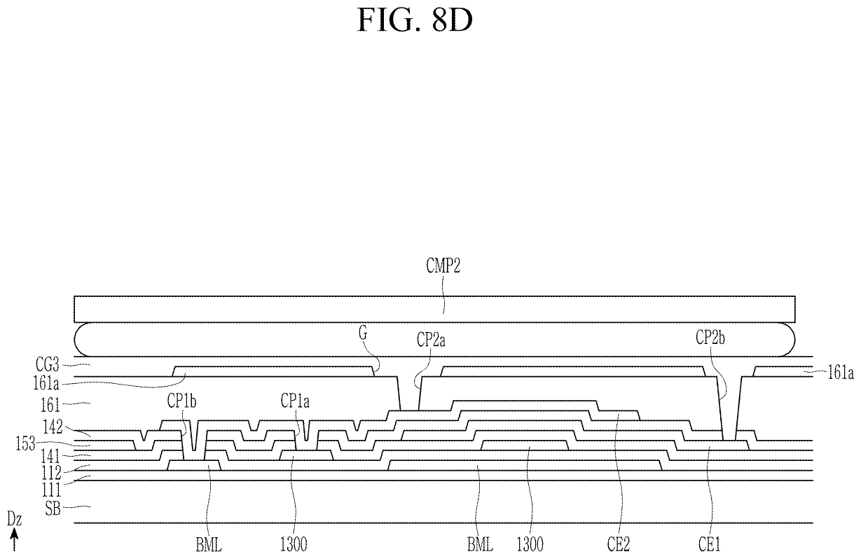

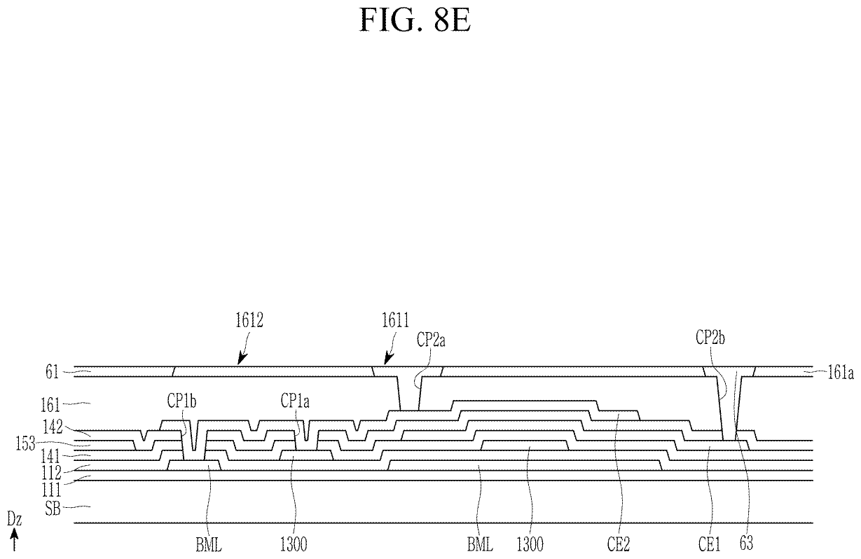

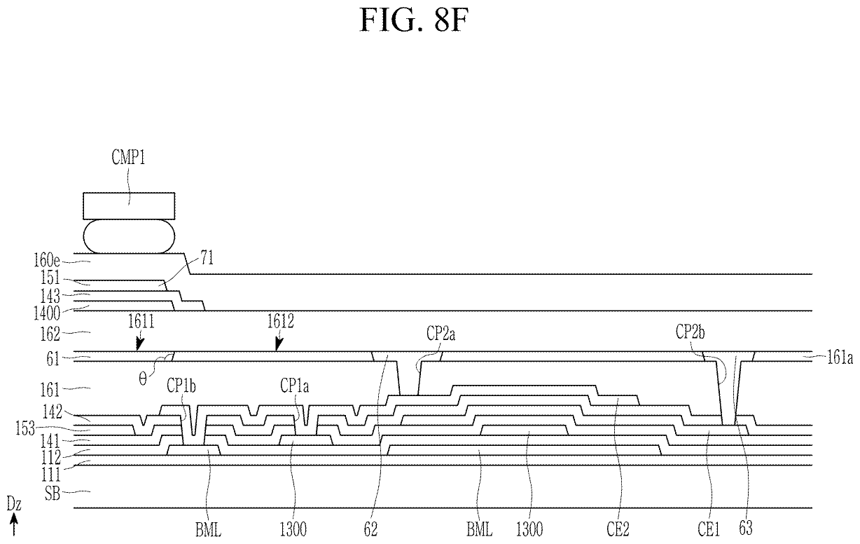

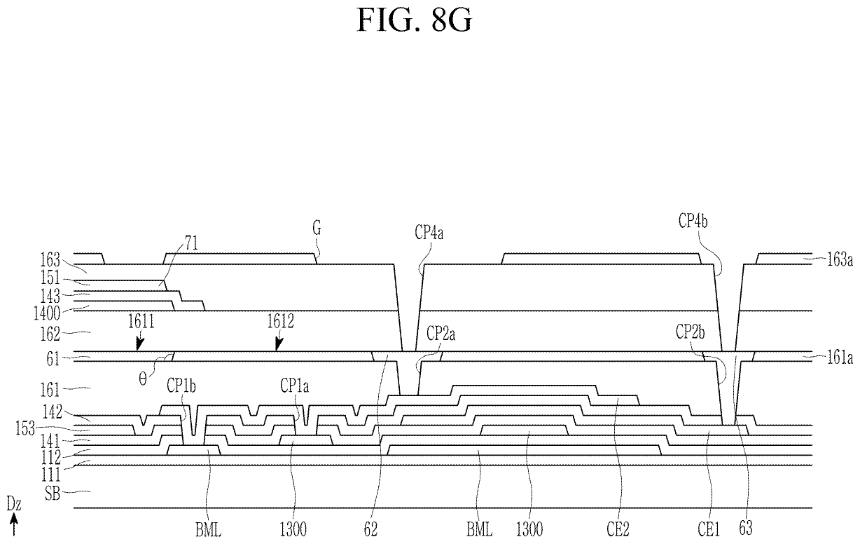

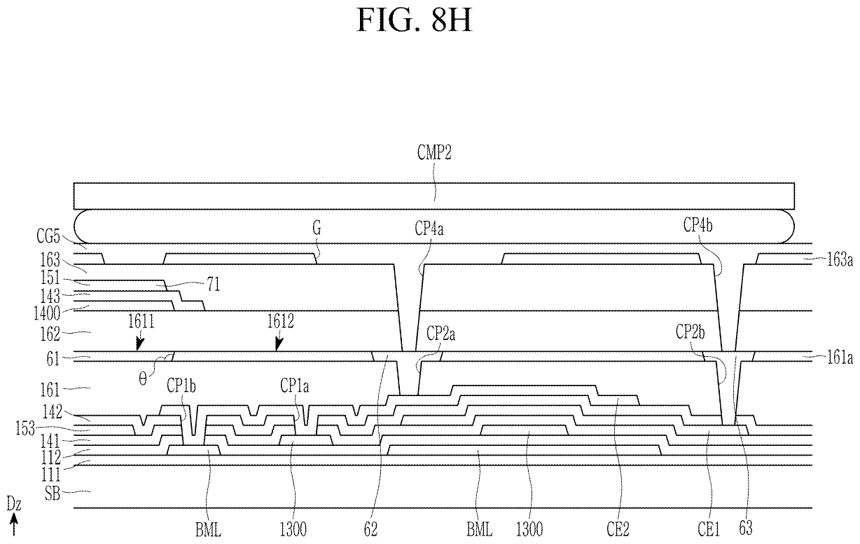

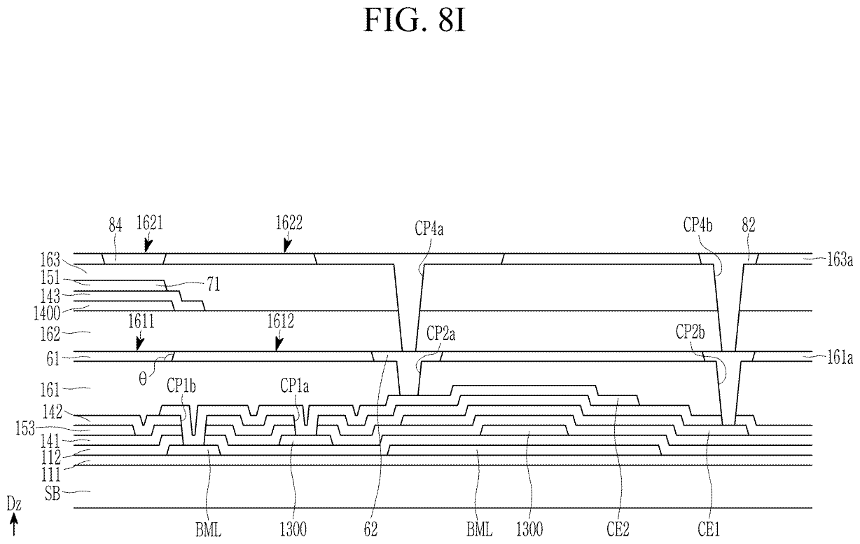

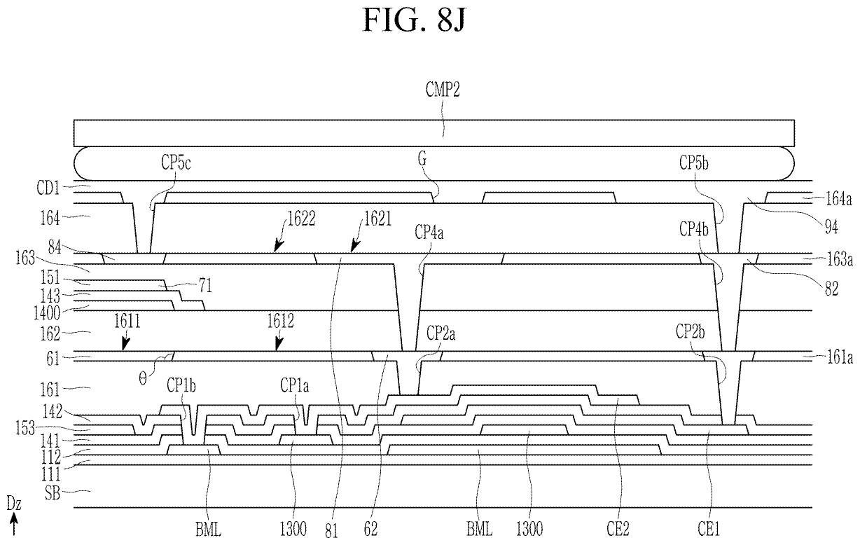

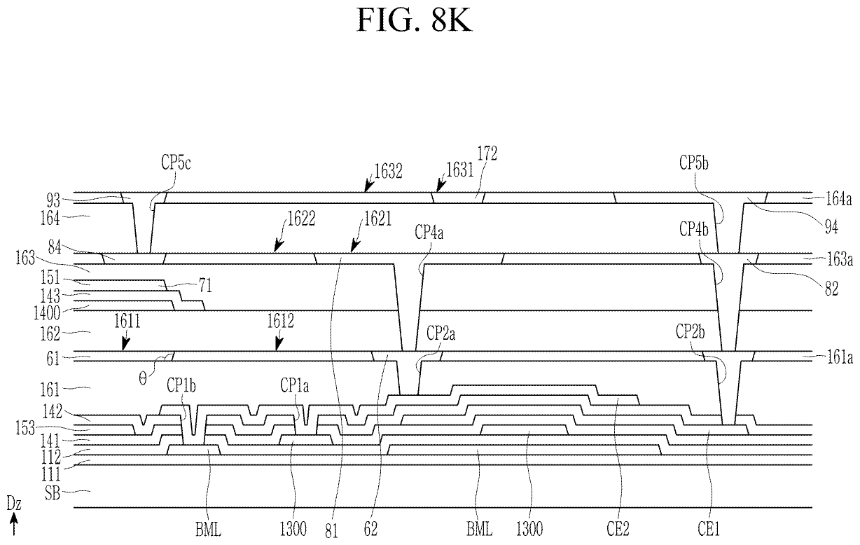

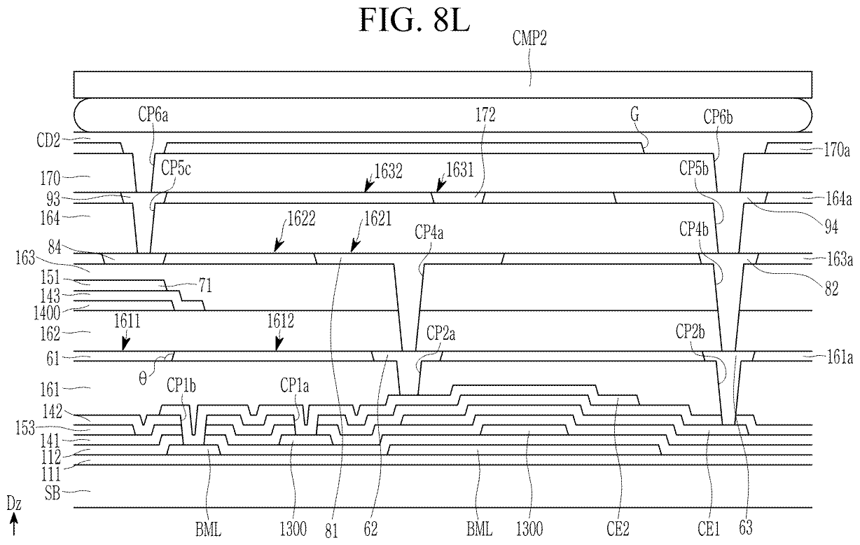

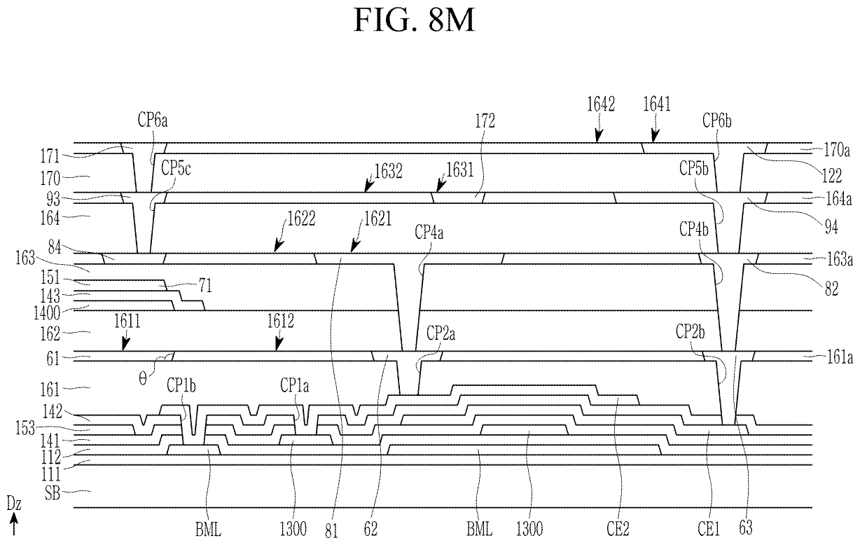

A manufacturing method according to the display device according to another embodiment is described with reference to FIG. 8A to FIG. 8M along with FIG. 6 and FIG. 7. FIG. 8A to FIG. 8M are schematic cross-sectional views showing a manufacturing method of a display device according to another embodiment.

Referring to FIG. 8A, a buffer layer 111 may be formed on a substrate SB and a metal layer BML may be formed on the buffer layer 111. A first buffer layer 112 may be formed on the metal layer BML and a first semiconductor layer 1300 may be formed on the first buffer layer 112. The first semiconductor layer 1300 may be formed to include a polycrystalline semiconductor. A first gate insulating layer 141 may be formed on the first semiconductor layer 1300, and a first gate conductor including an initialization control line 153, a light emission control line 154, and a first capacitor electrode CE1 may be formed on the first gate insulating layer 141.

A second gate insulating layer 142 may be deposited on the first gate conductor, a first contact hole CP1a exposing one portion of the first semiconductor layer 1300 may be formed in the second gate insulating layer 142 and the first gate insulating layer 141, a second contact hole CP1b exposing one portion of the metal layer BML may be formed in the second gate insulating layer 142, the first gate insulating layer 141, and the first buffer layer 112, and a third contact hole CP1c exposing another portion of the first semiconductor layer 1300 may be formed in the second gate insulating layer 142 and the first gate insulating layer 141.

A second gate conductor including a first initialization voltage layer 127 and a second capacitor electrode CE2 may be formed on the second gate insulating layer 142, an insulating layer 160d of which the height measured from the substrate surface along the first direction Dz may not be constant depending on the position may be stacked on the second gate conductor, and the surface of the insulating layer 160d may be polished by using a first planarization device CMP1. In the described embodiment, the first interlayer insulating layer 161 may be formed of one layer, however the disclosure is not limited thereto, and the first interlayer insulating layer 161 may be formed of a first layer which may include a silicon nitride and a second layer which may include a silicon oxide, and the first layer which may include a silicon nitride may serve as a stopper in the planarization process of the second layer which may include a silicon oxide. Accordingly, one portion of the first interlayer insulating layer 161 may have the same height as the height of the surface of the first layer.

Through this polishing process, as shown in FIG. 8B, the first interlayer insulating layer 161 with a constant height measured from the substrate surface along the first direction Dz may be formed. As shown in FIG. 8C and FIG. 6, a first side wall insulating layer 161a may be formed on the first interlayer insulating layer 161. The first side wall insulating layer 161a may have at least one depressed portion G. The depressed portion G may be formed corresponding to the position where the wiring of the third gate conductor CG3 may be formed. A fourth contact hole CP2a exposing the second capacitor electrode CE2 may be formed in the first interlayer insulating layer 161 and the first side wall insulating layer 161a, a fifth contact hole CP2b exposing the first capacitor electrode CE1 may be formed in the first interlayer insulating layer 161, the first side wall insulating layer 161a, and the second gate insulating layer 142, and a sixth contact hole CP2c exposing another portion of the first semiconductor layer 1300 (shown in FIG. 6) may be formed in the first interlayer insulating layer 161, the first side wall insulating layer 161a, the second gate insulating layer 142, and the first gate insulating layer 141. At this time, when the first interlayer insulating layer 161 and the first side wall insulating layer 161a may be made of different materials, each contact hole may be formed in different widths by different etching ratios. For example, as shown in FIG. 8C, the width of the portion in which the first side wall insulating layer 161a may be positioned in each contact hole may be formed to be larger.

Referring to FIG. 6 along with FIG. 8D, on the first interlayer insulating layer 161 and the first side wall insulating layer 161a, a third gate conductor CG3 may be formed to fill the depressed portion G, and the third gate conductor CG3 and the first side wall insulating layer 161a may be planarized by the second planarization process CMP2 to form a first connection portion 61, a second connection portion 62, a third connection portion 63, a fourth connection portion 64, and a fifth connection portion 65 which may be included in the third gate conductor CG3. At this time, by applying the slurry for polishing copper as described above as the second planarization process CMP2, the third gate conductor CG3 and the first side wall insulating layer 161a may be simultaneously planarized. For example, at this time, the third gate conductor CG3 may be copper wiring. By using the slurry for polishing copper including the catalyst with the single molecule which may include iron ions and the oxidizing agent, the Fenton reaction occurs, and accordingly, the copper oxide film may be formed at a high speed on the surface of the copper wiring, so the polishing of the third data conductor CD3 and the first side wall insulating layer 161a may be completed through one-step polishing without the dishing. Accordingly, as shown in FIG. 8E, the obtained first metal surface 1611 of the third data conductor CD3 and the first insulating surface 1612 of the first side wall insulating layer 161a may have the same height from the substrate and may have the polished flat surface. As described above, since the first side wall insulating layer 161a may be first formed and patterned and the third gate conductor CG3 may be formed, as shown in FIG. 8E, the angle between the lower surface and the side surface of the wirings included in the third gate conductor CG3 may be formed to be more than 90 degrees. The first side wall insulating layer 161a may be formed to not be disposed on the wirings included in the third gate conductor CG3, but to be disposed between these wirings.

Referring to FIG. 8F, on the first side wall insulating layer 161a and the third gate conductor CG3, a second interlayer insulating layer 162 may be formed. At this time, since the first insulating surface 1612 and the first metal surface 1611 of the first side wall insulating layer 161a and the third gate conductor CG3 of the portion where the second interlayer insulating layer 162 may be formed to already have the polished flat surfaces of the same height, the second interlayer insulating layer 162 may be formed with the constant height measured from the substrate surface without performing an additional planarization process or the like.

A second semiconductor layer 1400 may be formed on the second interlayer insulating layer 162, and a third gate insulating layer 143 to cover one portion of the second semiconductor layer 1400 may be formed on the second semiconductor layer 1400. A fourth gate conductor including a second scan line 152 and an initialization control line 153 may be formed on the third gate insulating layer 143 and on the fourth gate conductor, the insulating layer 160e of which the height measured from the substrate surface along the first direction Dz may not be constant is stacked, and the surface of the insulating layer 160e may be polished by using the first planarization device CMP1, and as shown in FIG. 8G, the third interlayer insulating layer 163 with a constant height measured from the substrate surface along the first direction Dz may be formed.

Referring to FIG. 6 along with FIG. 8G, the third side wall insulating layer 163a may be formed on the third interlayer insulating layer 163. The third side wall insulating layer 163a may have at least one depressed portion G. The depressed portion G may be formed corresponding to the position where the wiring of the fifth gate conductor CG5 may be formed. A seventh contact hole CP4a, an eighth contact hole CP4b, and a ninth contact hole CP4c exposing the second connection portion 62, the third connection portion 63, and the fifth connection portion 65 may be formed in the third interlayer insulating layer 163, the third side wall insulating layer 163a, and the second interlayer insulating layer 162, and a tenth contact hole CP4d, an eleventh contact hole CP4e, and a twelfth contact hole CP4f exposing one portion of the second semiconductor layer 1400 may be formed in the third interlayer insulating layer 163, the third side wall insulating layer 163a, and the third gate insulating layer 143.

Referring to FIG. 6 along with FIG. 8H, a fifth gate conductor CG5 may be formed on the third interlayer insulating layer 163 and the third side wall insulating layer 163a to fill the depressed portion G, and the fifth gate conductor CG5 and the third side wall insulating layer 163a may be planarized by the second planarization process CMP2, and as shown in FIG. 8I, a sixth connection portion 81, a seventh connection portion 82, an eighth connection portion 83, a ninth connection portion 84, and a tenth connection portion 85 included in the fifth gate conductor CG5 may be formed. At this time, the fifth gate conductor CG5 may be copper wiring, and the fifth gate conductor CG5 and the third side wall insulating layer 16a may be simultaneously planarized by applying the slurry for polishing copper as described above as the second planarization process CMP2. Thereby, as shown in FIG. 8I, the first metal surface 1621 of the fifth gate conductor CG5 and the first insulating surface 1622 of the third side wall insulating layer 163a may have the same height from the substrate and may have a polished flat surface.

Referring to FIG. 8J, a fourth interlayer insulating layer 164 may be formed on the fifth gate conductor CG5 and the third side wall insulating layer 163a. At this time, since the second metal surface 1621 and the second insulating surface 1622 of the fifth gate conductor CG5 and the third side wall insulating layer 163a of the portion where the fourth interlayer insulating layer 164 may be formed already have the polished flat surface of the same height, so the fourth interlayer insulating layer 164 having a constant height measured from the substrate surface may be formed without performing an additional planarization process.

Referring to FIG. 6 along with FIG. 8J, a fourth side wall insulating layer 164a may be formed on the fourth interlayer insulating layer 164. The fourth side wall insulating layer 164a may have at least one depressed portion G. The depressed portion G may be formed corresponding to the position where the wiring of the first data conductor CD1 may be formed. A thirteenth contact hole CP5a exposing the eighth connection portion 83, a fourteenth contact hole CP5b exposing the sixth connection portion 82, a fifteenth contact hole CP5c exposing the ninth connection portion 84, and a sixteenth contact hole CP5d exposing the tenth connection portion 85 may be formed in the fourth interlayer insulating layer 164 and the fourth side wall insulating layer 164a.

A first data conductor CD1 may be formed to fill the depressed portion G on the fourth interlayer insulating layer 164 and the fourth side wall insulating layer 164a, and the first data conductor CD1 and the fourth side wall insulating layer 164a may be planarized by a second planarization process CMP2, and as shown in FIG. 8K, a driving voltage line 172, a reference voltage layer 176, an eleventh connection portion 93, and a twelfth connection portion 94 included in the first data conductor CD1 may be formed. At this time, the first data conductor CD1 may be copper wiring, and the first data conductor CD1 and the fourth side wall insulating layer 164a may be simultaneously planarized by applying the slurry for polishing copper as described above as the second planarization process CMP2. Thereby, as shown in FIG. 8K, the third metal surface 1631 of the first data conductor CD1 and the third insulating surface 1632 of the fourth side wall insulating layer 164a may have the same height from the substrate and may have a polished flat surface.

Referring to FIG. 8L, a first insulating layer 170 may be formed on the first data conductor CD1 and the fourth side wall insulating layer 164a. At this time, since the third metal surface 1631 and the third insulating surface 1632 of the first data conductor CD1 and the fourth side wall insulating layer 164a of the portion where the first insulating layer 170 may be formed already have the polished flat surfaces of the same height, it may be possible to form the first insulating layer 170 with a constant height measured from the substrate surface without an additional planarization process.

Referring to FIG. 6 along with FIG. 8L, a first side wall insulating layer 170a may be formed on the first insulating layer 170. The first side wall insulating layer 170a may have at least one depressed portion G. The depressed portion G may be formed corresponding to the position where the wiring of the second data conductor CD2 may be formed. A seventeenth contact hole CP6a and an eighteenth contact hole CP6b exposing the eleventh connection portion 93 and the twelfth connection portion 94 may be formed in the first insulating layer 170 and the first side wall insulating layer 170a.

A second data conductor CD2 to fill the depressed portion G may be formed on the first insulating layer 170 and the first side wall insulating layer 170a, and the second data conductor CD2 and the first side wall insulating layer 170a may be planarized by the second planarization process CMP2, and as shown in FIG. 8M, a data line 171 and a thirteenth connection portion 122 included in the second data conductor CD2 may be formed. At this time, the second data conductor CD2 may be copper wiring, and the second data conductor CD2 and the first side wall insulating layer 170a may be simultaneously planarized by applying the slurry for polishing copper as described above as the second planarization process CMP2. Thereby, as shown in FIG. 8M, the fourth metal surface 1641 of the second data conductor CD2 and the fourth insulating surface 1642 of the first side wall insulating layer 170a may have the same height from the substrate and may have a polished flat surface.

A second insulating layer 180 may be formed on the second data conductor CD2 and the first side wall insulating layer 170a, and a nineteenth contact hole CP7a exposing the twelfth connection portion 94 may be formed in the second insulating layer 180. A pixel electrode 191 connected to the thirteenth connection portion 122 through the nineteenth contact hole CP7a may be formed on the second insulating layer 180, a pixel definition layer 350 may be formed on the pixel electrode 191, and an emission layer 370 may be formed in the pixel opening 3405 of the pixel definition layer 350, and a common electrode 270 may be formed on the emission layer 370 and the pixel definition layer 350, thereby forming the display device shown in FIG. 5 to FIG. 7.

As such, according to the manufacturing method of the display device according to the embodiment, when polishing the third gate conductor CG3, the fifth gate conductor CG5, the first data conductor CD1, and the second data conductor CD2 forming the metal wiring, it may be possible to polish them together with the insulating layers in only one step by using the slurry for polishing copper which may include the catalyst which may include the single molecule with iron ions and the oxidizing agent. Accordingly, it may be possible to prevent the dishing from occurring on the surface while simplifying the manufacturing process, and at the same time, the surface of the subsequently formed layer may be formed to be planarized without an additional process. Even if multiple wirings may be stacked, it may be possible to form the device without increasing the thickness of the entire device, so that it may be possible to form a high resolution high-step-difference stacked structure. In an embodiment, it may be described that the third gate conductor CG3, the fifth gate conductor CG5, the first data conductor CD1, and the second data conductor CD2 may be all made of copper wiring and may be manufactured by applying the slurry for polishing copper, but the disclosure is not limited thereto, and of course, it may also be possible to be applied to one or more of these, and it is not limited to the configuration described in the embodiments.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A slurry for polishing copper, comprising:
an abrasive;
a catalyst including a single molecule having an iron ion;
a polishing suppressant; and
an oxidizing agent.

2. The slurry for polishing copper of claim 1, wherein the catalyst includes at least one selected from iron cyanide, iron nitride, iron citrate, iron chloride, iron sulfate, iron oxalate, iron bromide, and iron phosphate.

3. The slurry for polishing copper of claim 1, wherein the polishing suppressant is a material that is combined with a metal ion with one ligand.

4. The slurry for polishing copper of claim 3, wherein the polishing suppressant is at least one selected from arginine, ethylenediaminetetraacetic acid (EDTA), glycine, citric acid, diethylenetriamine pentamethylene phosphonic acid (DTPMPA), 1-hydroxy ethylidene-1, and 1-diphosphonic acid.

5. The slurry for polishing copper of claim 1, wherein the oxidizing agent is at least one selected from hydrogen peroxide, ammonium persulfate, benzoyl peroxide, calcium peroxide, barium peroxide, and sodium peroxide.

6. The slurry for polishing copper of claim 1, wherein the abrasive is at least one selected from silica, zirconia, alumina, ceria, and titania.

7. The slurry for polishing copper of claim 1, wherein the catalyst and the oxidizing agent react to generate hydroxyl radicals.

8. The slurry for polishing copper of claim 1, wherein the slurry for polishing copper has a pH in a range of about 8 to about 10.

9. The slurry for polishing copper of claim 1, wherein a content of the catalyst is in a range of about 0.25 to about 2.0 wt %, based on the entire weight of the slurry for polishing copper.

10. The slurry for polishing copper of claim 1, wherein a content of the oxidizing agent is in a range of about 0.5 to about 2.5 wt %, based on the entire weight of the slurry for polishing copper.

11. The slurry for polishing copper of claim 1, wherein a content of the polishing suppressant is in a range of about 0.25 to about 2.0 wt %, based on the entire weight of the slurry for polishing copper.

12. A display device comprising:
a first interlayer insulating layer positioned on a substrate; and
at least one first signal line and one first side wall insulating layer positioned on the first interlayer insulating layer, wherein
the first side wall insulating layer is positioned between at least two of the first signal lines, and
a height measured from a surface of the substrate to a surface of the at least one first signal line along a first direction perpendicular to the surface of the substrate is a same as a height measured from the surface of the substrate to a surface of the first side wall insulating layer along the first direction perpendicular to the surface of the substrate.

13. The display device of claim 12, wherein the at least one first signal line includes copper (Cu).

14. The display device of claim 12, wherein a surface of at the least one first signal line and a surface of the first side wall insulating layer are each a polished surface.

15. The display device of claim 12, wherein in at least one first signal line, an angle between the lower surface of the first signal line and the side surface of the first signal line is 90 degrees or more.

16. The display device of claim 12, wherein the first interlayer insulating layer includes one or more of a silicon oxide and a silicon nitride.

17. The display device of claim 12, further comprising:
a second interlayer insulating layer positioned on the at least one first signal line and the first side wall insulating layer; and
at least one second signal line and a second side wall insulating layer positioned on the second interlayer insulating layer, wherein
the second side wall insulating layer is positioned between at least two of the second signal lines,
a height measured from the surface of the substrate to a surface of the at least one second signal line along the first direction perpendicular to the surface of the substrate is a same as a height measured from the surface of the substrate to a surface of the second side wall insulating layer along the first direction perpendicular to the surface of the substrate.

18. The display device of claim 17, wherein the at least one second signal line includes copper (Cu).

19. The display device of claim 17, wherein a surface of the at least one second signal line and a surface of the second side wall insulating layer are each a polished surface.

20. The display device of claim 17, wherein in at least one second signal line, an angle between the lower surface of the second signal line and the side surface of the second signal line is 90 degrees or more.

21. A manufacturing method of a display device comprising:
forming a first interlayer insulating layer on a substrate;
forming a first side wall insulating layer including at least one depression on the first interlayer insulating layer;
forming a first conductive layer to cover at least one depression on the first interlayer insulating layer and the first side wall insulating layer; and
forming at least one first signal line by polishing the first conductive layer and the first side wall insulating layer, wherein
a height measured from a surface of the substrate to a surface of the at least one first signal line along a first direction perpendicular to the surface of the substrate is a same as a height from the surface of the substrate to a surface of the first side wall insulating layer along the first direction perpendicular to the surface of the substrate.

22. The manufacturing method of the display device of claim 21, wherein
the at least one first signal line includes copper (Cu), and
the polishing of the upper part of the first conductive layer is performed by using a slurry for polishing copper including:
an abrasive;
a catalyst including a single molecule with an iron ion;
a polishing suppressant; and
an oxidizing agent.

23. The manufacturing method of the display device of claim 22, further comprising:
planarizing the surface of the first interlayer insulating layer, wherein
the planarization of the surface of the first interlayer insulating layer does not use the slurry for polishing copper.

24. The manufacturing method of the display device of claim 21, wherein a surface of at least one signal line and a surface of the first side wall insulating layer are each polished by the polishing of the upper part of the first conductive layer.

25. The manufacturing method of the display device of claim 21, further comprising:
forming a second interlayer insulating layer on the at least one first signal line and the first side wall insulating layer, wherein
the forming of the second interlayer insulating layer does not include an additional planarization process.

26. The manufacturing method of the display device of claim 25, further comprising:
forming a second side wall insulating layer including at least one depression on the second interlayer insulating layer; and
forming a second conductive layer to cover at least one depression on the second interlayer insulating layer and the second side wall insulating layer, wherein
an upper part of the second conductive layer is polished to form at least one second signal line, and
a height measured from the surface of the substrate to a surface of the at least one second signal line along the first direction perpendicular to the surface of the substrate is a same as a height measured from the surface of the substrate to a surface of the second side wall insulating layer along the first direction perpendicular to the surface of the substrate.

27. The manufacturing method of the display device of claim 26, wherein
the at least one second signal line includes copper (Cu), and
the polishing of the upper part of the second conductive layer is performed by using a slurry for polishing copper including:
an abrasive;
a catalyst including a single molecule with an iron ion;
a polishing suppressant; and
an oxidizing agent.

28. The manufacturing method of the display device of claim 26, wherein a surface of the at least one signal line and a surface of the second side wall insulating layer are each polished by the polishing of the upper part of the second conductive layer.
